(19) United States
(12) Patent Application Publication
(10) Pub. No.: US 2020/0056284 A1
(43) Pub. Date: Feb. 20, 2020

(54) Chemical vapor deposition wafer carriers

(71) Applicant: Veeco Instruments Inc., Plainview, NY (US)

(72) Inventors: Bojan Mitrovic, Somerset, NJ (US); Yuliy Rashkovsky, Millburn, NJ (US); Eric Armour, Pennington, NJ (US)

(21) Appl. No.: 15/999,697

(22) Filed: Aug. 20, 2018

(51) Int. Cl. C23C 16/458; H01L 21/687

(52) U.S. Cl. CPC C23C 16/4584; H01L 21/68764; H01L 21/68771; H01L 21/68721

(57) ABSTRACT

A wafer carrier has a plurality of built-up pockets connected by raised interstitial spaces on a base. Top cover plates are affixed to the base by fasteners and separated from direct thermal contact by spacers.

### TECHNICAL FIELD

The present disclosure relates generally to semiconductor fabrication technology. More particularly, the present disclosure relates to a wafer carrier assembly for a chemical vapor deposition (CVD) reactor.

### BACKGROUND

Certain processes for fabrication of semiconductors can require a complex process for growing epitaxial layers to create multilayer semiconductor structures for use in fabrication of high performance devices, such as light emitting diodes (LEDs), laser diodes, optical detectors, power electronics, and field effect transistors. In this process, the epitaxial layers are grown through a general process called Chemical Vapor Deposition (CVD). One type of CVD process is called Metal Organic Chemical Vapor Deposition (MOCVD). In MOCVD, reactant gases are introduced into a sealed reactor chamber within a controlled environment that enables the reactor gas to be deposited on a substrate (commonly referred to as a wafer) to grow thin epitaxial layers. Examples of current product lines for such manufacturing equipment include the TurboDisc®, MaxBright®, and EPIK® families of MOCVD systems, and the PROPEL® Power GaN MOCVD system, all manufactured by Veeco Instruments Inc. of Plainview, N.Y.

During epitaxial layer growth, a number of process parameters are controlled, such as temperature, pressure, and gas flow rate, to achieve desired quality in the epitaxial layers. Different layers are grown using different materials and process parameters. For example, devices formed from compound semiconductors such as III-V semiconductors, typically are formed by growing a series of distinct layers. In this process, the wafers are exposed to a combination of reactant gases, typically including a metal organic compound formed using an alkyl source including a group III metal such as gallium, indium, aluminum, and combinations thereof, and a hydride source including a Group V element such as NH₃, AsH₃, PH₃, or an Sb metalorganic, such as tetramethyl antimony. Generally the alkyl and hydride sources are combined with a carrier gas, such as N₂ and/or H₂, which does not participate appreciably in the reaction. In these processes, the alkyl and hydride sources flow over the surface of the wafer and react with one another to form a III-V compound of the general formula InₓGa_{Y}Al_{z}N_{A}As_{B}P_{C}Sb_{D}, where X+Y+Z equals approximately one, A+B+C+D equals approximately one, and each of X, Y, Z, A, B, C, and D can be between zero and one. In other processes, commonly referred to as “halide” or “chloride” processes, the Group III metal source is a volatile halide of the metal or metals most commonly a chloride such as GaCl₂. In yet other processes, bismuth is used in place of some or all of the other Group III metals.

A suitable substrate for the reaction can be in the form of a wafer having metallic, semiconducting, and/or insulating properties. In some processes the wafer can be formed of sapphire, aluminum oxide, silicon (Si), silicon carbide (SiC), gallium arsenide (GaAs), indium phosphide (InP), indium arsenide (InAs), gallium phosphide (GaP), aluminum nitride (AlN), silicon dioxide (SiO2), and the like.

In a CVD process chamber, one or more wafers are positioned within a tray, commonly referred to as a wafer carrier, so that the top surface of each wafer is exposed, thereby providing a uniform exposure of the top surface of the wafer to the atmosphere within the reactor chamber for the deposition of semiconductor materials. The wafer carrier is commonly rotated at a rotation speed on the order from about 50 to 1500 RPM or higher. While the wafer carrier is rotated, the reactant gases are introduced into the chamber from a gas distribution device, positioned upstream of the wafer carrier. The flowing gases pass downstream toward the wafer carrier and wafers, desirably in a laminar flow. One such example of a CVD process chamber is disclosed in U.S. Pat. Publ. No. 2017/0253967, the contents of which are hereby incorporated by reference herein.

During the CVD process, the wafer carrier is maintained at a desired elevated temperature by heating elements, often positioned beneath the wafer carrier. Therefore, heat is transferred from the heating elements to the bottom surface of the wafer carrier and flows upwardly through the wafer carrier to the one or more wafers. Depending on the process, the temperature of the wafer carrier is maintained on the order of between 700-1200° C. The reactive gases, however, are introduced into the chamber by the gas distribution device at a much lower temperature, typically 200° C., or lower, so as to inhibit premature reaction of the gases.

### SUMMARY OF THE DISCLOSURE

Embodiments of the present disclosure provide an improved wafer reactor or wafer carrier in which one or more thermal transfer characteristics between the reactor and the wafers are enhanced.

One embodiment of the present disclosure provides a wafer carrier with built-up wafer retention pockets in a ring concentric with the wafer carrier.

The summary above is not intended to describe each illustrated embodiment or every implementation of the present disclosure. The figures and the detailed description that follow more particularly exemplify these embodiments.

### BRIEF DESCRIPTION OF THE DRAWINGS

The disclosure can be more completely understood in consideration of the following detailed description of various embodiments of the disclosure, in connection with the accompanying drawings, in which:

FIG. 1 is a schematic view depicting a CVD reactor in accordance with an embodiment of the disclosure.

FIG. 2 is a perspective view of an 11-pocket wafer carrier according to an embodiment.

FIG. 3 is a top view of the 11-pocket wafer carrier of FIG. 2.

FIG. 4 is a bottom view of the 11-pocket wafer carrier of FIG. 2.

FIGS. 5A and 5B are side views of the 11-pocket wafer carrier of FIG. 2.

FIG. 6 is an exploded view of the 11-pocket wafer carrier of FIG. 2.

FIG. 7 is a detailed view of one pocket of the 11-pocket wafer carrier of FIG. 2.

FIG. 8 is a detailed view of one pocket of the 11-pocket wafer carrier of FIG. 2 in the exploded view of FIG. 6.

FIG. 9 is a perspective partial view of the 11-pocket wafer carrier of FIG. 2, showing the top covers thereof.

FIG. 10 is a top view of the top covers of FIG. 9.

FIG. 11 is a partial perspective view of the 11-pocket wafer carrier of FIG. 2, showing the base thereof.

FIG. 12 is a top view of the base of FIG. 11.

FIG. 13 is a cross-sectional view of the base of FIG. 11.

FIG. 14 is a perspective view of a 14-pocket wafer carrier according to an embodiment.

FIG. 15 is a top view of the 14-pocket wafer carrier of FIG. 14.

FIG. 16 is a bottom view of the 14-pocket wafer carrier of FIG. 14.

FIGS. 17A and 17B are side views of the 14-pocket wafer carrier of FIG. 14.

FIG. 18 is an exploded view of the 14-pocket wafer carrier of FIG. 14

FIG. 19 is a detailed view of one pocket of the 14-pocket wafer carrier of FIG. 14.

FIG. 20 is a detailed view of one pocket of the 14-pocket wafer carrier of FIG. 4 in the exploded view of FIG. 18.

FIG. 21 is a perspective partial view of the 14-pocket wafer carrier of FIG. 14, showing the top covers thereof

FIG. 22 is a top view of the top covers of FIG. 21.

FIG. 23 is a perspective view of the 14-pocket wafer carrier of FIG. 14, showing the base thereof.

FIG. 24 is a top view of the base of FIG. 23.

FIG. 25 is a cross-sectional view of the base of FIG. 23.

FIG. 26 is a perspective view of a 7-pocket wafer carrier according to an embodiment.

FIG. 27 is a top plan view of the wafer carrier of FIG. 26. FIG. 28 is a bottom view of the wafer carrier of FIG. 26.

FIG. 29 is a side view of the wafer carrier of FIG. 26.

FIG. 30 is an exploded view of the wafer carrier of FIG. 26.

FIG. 31 is a detailed view of the section 31 shown in FIG. 30.

FIG. 32 is a detailed view of the section 32 shown in FIG. 30.

FIG. 33 is a cutaway view of the wafer carrier of FIG. 26, shown along the cutaway line 33 depicted in FIG. 27.

FIG. 34 is a perspective view of a 16-pocket wafer carrier with two pockets arranged along the outside rim, according to another embodiment.

FIG. 35 is a top plan view of the wafer carrier of FIG. 34. FIGS. 36A and 36B are a side view of the wafer carrier of FIG. 34.

FIG. 37 is a bottom view of the wafer carrier of FIG. 34.

FIG. 38 is an exploded view of the wafer carrier of FIG. 34.

FIG. 39 is a perspective view of the wafer carrier of FIG. 34 with the top plate removed.

FIG. 40 is a detailed view of section 40 indicated in FIG. 39.

FIG. 41 is a detailed view of section 41 indicated in FIG. 34.

FIG. 42 is a cutaway view of the wafer carrier of FIG. 34, shown along the cutawyline 42 depicted in FIG. 35.

FIG. 43 is a perspective view of a 13-pocket wafer carrier with two pockets arranged along the outside rim, according to another embodiment.

FIG. 44 is a top view of the wafer carrier of FIG. 43.

FIG. 45 is a bottom view of the wafer carrier of FIG. 43.

FIGS. 46A and 46B are side views of the wafer carrier of FIG. 43.

FIG. 47 is a perspective view of a wafer carrier assembly according to another embodiment.

FIGS. 48, 49A, 49B, and 50 are a top plan view, side view, front view, and bottom view of the wafer carrier assembly of FIG. 47, respectively.

While embodiments of the disclosure are amenable to various modifications and alternative forms, specifics thereof shown by way of example in the drawings will be described in detail. It should be understood, however, that the intention is not to limit the disclosure to the particular embodiments described. On the contrary, the intention is to cover all modifications, equivalents, and alternatives falling within the spirit and scope of the subject matter as defined by the claims.

### DETAILED DESCRIPTION

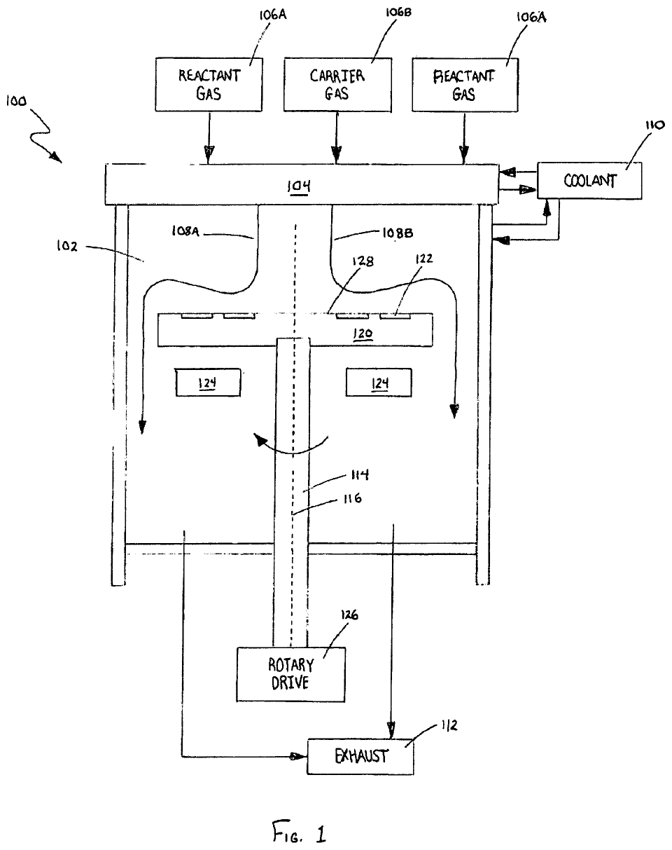

Referring to FIG. 1, a schematic view of a CVD reactor 100 is depicted in accordance with an embodiment of the disclosure. The reactor 100 defines a process chamber 102 configured to serve as a process environment space. A gas distribution device or injector block 104 is arranged at one end of the process chamber 102. The end of the process chamber 102 in which the injector block 104 is arranged can be referred to as the “top” end of the process chamber 102. This end of the chamber typically, but not necessarily, is disposed at the top of the chamber in the normal gravitational frame of reference. Thus, the downward direction as used herein refers to as the direction away from the injector block 104; whereas the upward direction refers to the direction within the chamber, toward the injector block 104, regardless of whether the instructions are aligned with the gravitational upward and downward directions. Similarly, the “top” and “bottom” surfaces of elements may be described herein with reference to the frame of reference of the process chamber 102 and the injector block 104.

The injector block 104 can be operably coupled to one or more gas supplies 106A/B for supplying gases to be used in the CVD process, such as reactant and carrier gases. The injector block 104 is arranged to receive the various gases from the gas supplies 106A/B, and direct the flow of the gases 108A/B into the reactor chamber 102 in a generally downward direction. In one embodiment, the injector block 104 includes a coolant system 110 configured to circulate a cooling fluid to maintain the injector block 104 at a desired temperature during operation. The coolant system 110 can also be configured to circulate a cooling fluid through the walls of the process chamber 102. The process chamber 102 is also equipped with an exhaust system 112 configured to remove spent gases from the interior of the chamber 102, so as to enable a continuous flow of gas in the downward direction from the injector block 104.

A spindle 114 can be arranged within the process chamber 102, so that a central axis 116 of the spindle 114 extends in the upward/downward direction. The spindle 114 can be mounted within the process chamber 102 by a conventional rotary pass-through device incorporating bearings and seals so that the spindle 114 can rotate while maintaining a seal with the walls of the process chamber 102.

In alternative embodiments, wafer carriers can be mounted in a drum-drive or other system, not necessarily one driven by a single spindle. In still other embodiments, multiple spindles can be used to drive the wafer carrier.

Wafer carrier 120 can be releasably mounted to the top end of the spindle 114. The wafer carrier 120 can have one or more pockets 122 into which wafers are held and onto which semiconductor materials can be epitaxially grown. The wafer carrier 120 can have a generally circular cross-section, arranged about the central axis 116. A heating element 124 can be mounted within the process chamber 102 and at least partially surround the spindle 114. Accordingly, in one embodiment, the process chamber 102, injector block 104, spindle 114, wafer carrier 120, and heating element 124 are arranged symmetrically about the central axis 116. The spindle 114 can be connected to a rotary drive mechanism 126, such as an electric motor drive, configured to rotate the spindle 114 and wafer carrier 120 at a desired speed. In one embodiment, the rotary drive mechanism is configured to rotate the spindle 114 at a rotational speed of between 50-1500 RPM.

Process gas can be introduced into the process chamber 102 through the injector block 104. Following introduction, the process gas passes downwardly toward the wafer carrier 120 and over the top surface 128 of the wafer carrier 120 where the wafers are held. The flow of process gas 108A/B continues to flow around the periphery of the wafer carrier 120 and is eventually exhausted from the process chamber 102 through the exhaust system 112. Often the process gas in proximity to the top surface 128 is predominantly composed of a carrier gas, such as H₂ and/or N₂, with some amount of first and second reactive gas components. In one embodiment, the first reactive gas component can be an alkyl source Group III metal, and the second reactive gas component can be a hydride source Group V element.

The heating element 124 can transfer heat to the wafer carrier 120, principally by radiant heat transfer. In other embodiments, the wafer carrier 120 can be heated via inductive heat transfer. The applied heat from the heating elements 124 is transferred upwardly through the body of the wafer carrier 120 to the top surface 128 thereof. Some portion of the heat on the top surface 128 of the wafer carrier 120 is transferred to the wafers and the process gas 108A/B passing over the top surface one twenty. Inadvertently, some portion of the heat is also transferred to cooler elements within the process chamber 102, such as the walls of the process chamber 102 and the injector block 104.

Pyrolyzed gas is desirably removed from the process chamber 102 prior to accumulating on any of these cooler structures, particularly as condensation can occur more rapidly on relatively cooler surfaces. To aid in the removal of pyrolyzed gas, in one embodiment, the wall structure of the process chamber 102 can form an upper and lower shutter configured to encourage downward gas flow, thereby reducing or eliminating any vortex that would otherwise recirculate hot pirate ties pyrolyzed gases back upwards toward relatively cooler surfaces, such as the injector block 104, to condense.

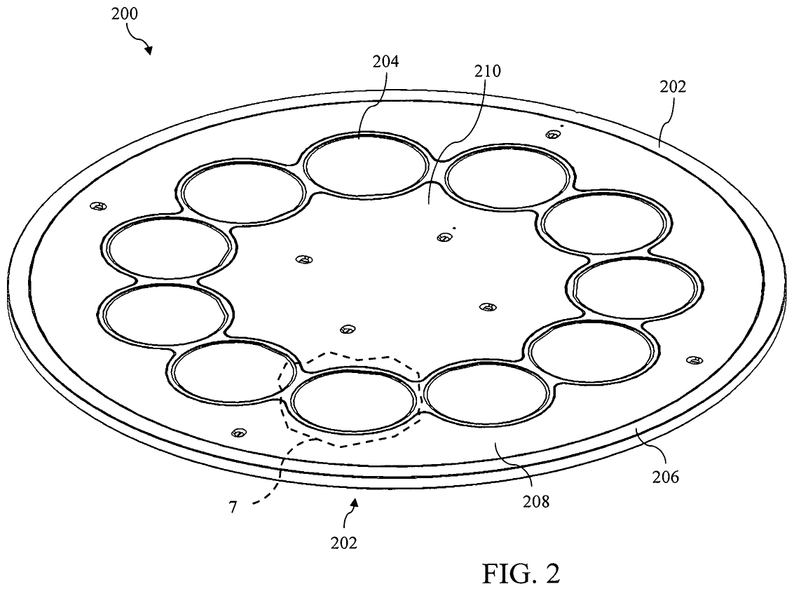

FIG. 2 is a perspective view of a wafer carrier 200 according to an embodiment. Wafer carrier 200 includes a base 202 defining an interconnected series of pockets 204 in this embodiment. Base 202 may also include rim 206. Base 200 is covered on one side by outer top cover 208 and inner top cover 210, but for the pockets 204 and rim 206 in this embodiment. Each pocket 204 is generally circular but for a “flat” portion as shown in FIG. 2. If the pocket 204 were perfectly circular, pockets arranged therein could rotate freely during CVD. With a “flat,” the pocket is prevented from rotation due to a keyed interconnection between the “flat” and a corresponding flattened or straight portion of the substrate arranged therein.

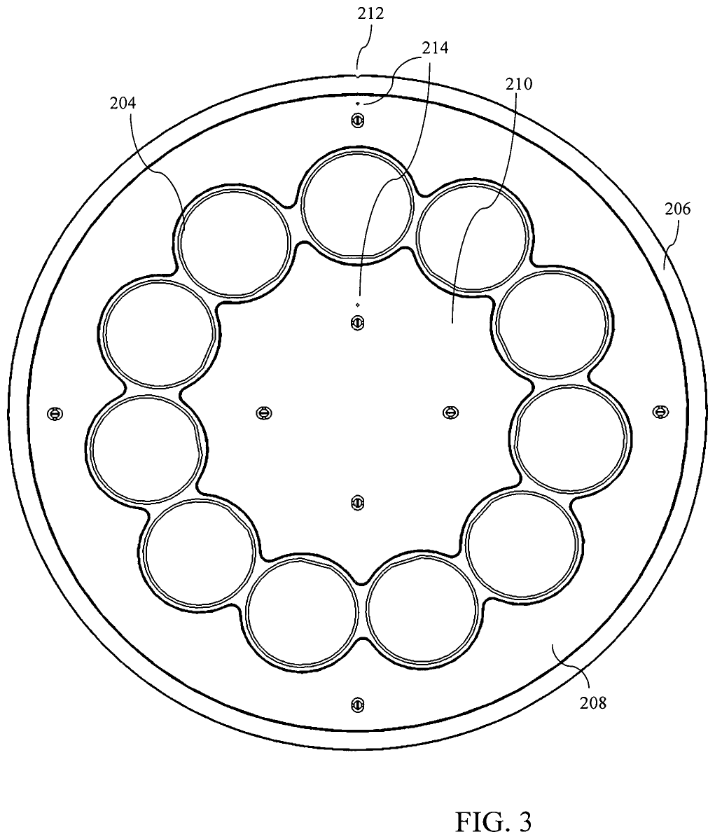

FIG. 3 is a top view of wafer carrier 200. As shown in FIG. 3, base 202 defines a notch 212 on a radially outer edge thereof. Notch 212 can be used for defining a rotational position of the wafer carrier 200, such as for loading or unloading from another device (not shown) two which base 202 can be attached during CVD. Similarly, top plates 208 and 210 each can include a corresponding indicator 214. When properly aligned, each of the indicators 214 may be radially aligned with notch 212 as shown in FIG. 3. Alternatively, proper alignment may be indicated by indicators 214 being radially offset from notch 212 by a predetermined amount.

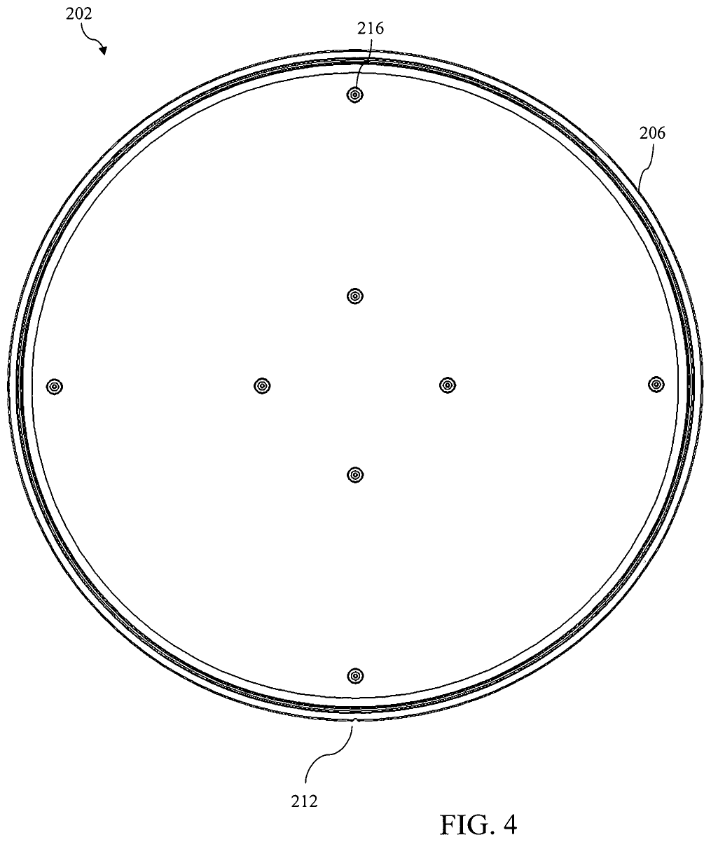

FIG. 4 is a bottom view of base 202. As shown in FIG. 4, base 202 includes an edge profile corresponding to rim 206 as well as another device, such as a reactor (not shown) in which base 202 can be arranged. FIG. 4 also depicts four connectors 216, which pass through wafer carrier 200 from top to bottom and are configured to hold top plates 208 and 210 to base 202. In alternative embodiments, it should be understood that the positions of connectors 216 could vary. Furthermore, a variety of connectors 216 can be used. In the embodiment shown in FIG. 4, connectors 216 are threaded screws inserted through top plates 208 or 210, each with a corresponding nut on the opposite side of base 202. Alternatively, connectors 216 could be rivets, bolts, or any other type of fastener that can be engaged to hold top plates 208 or 210 to base 202. In some embodiments, connectors 216 do not pass through base 202, but instead screw directly into base 202 to hold top plates 208 or 210 thereto. Contrariwise, in some embodiments connectors 216 pass through base 202 and engage with top plate 208 or top plate 210 without passing through.

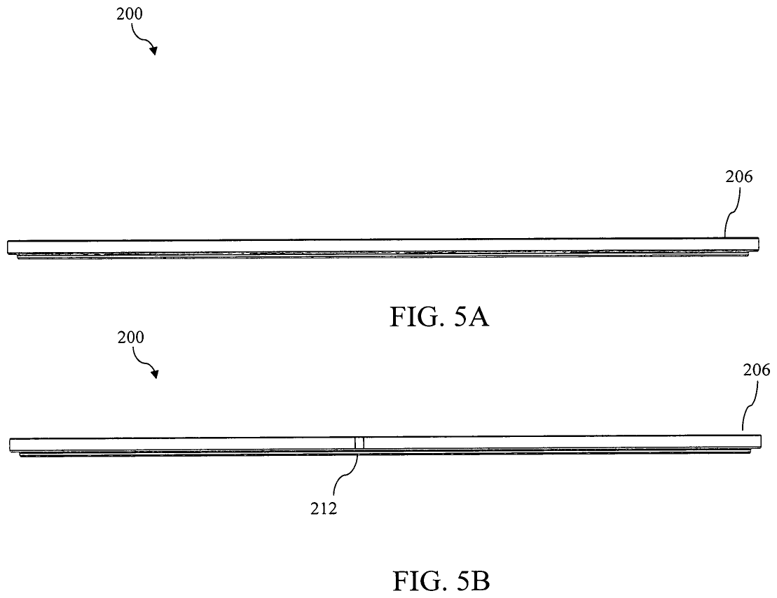

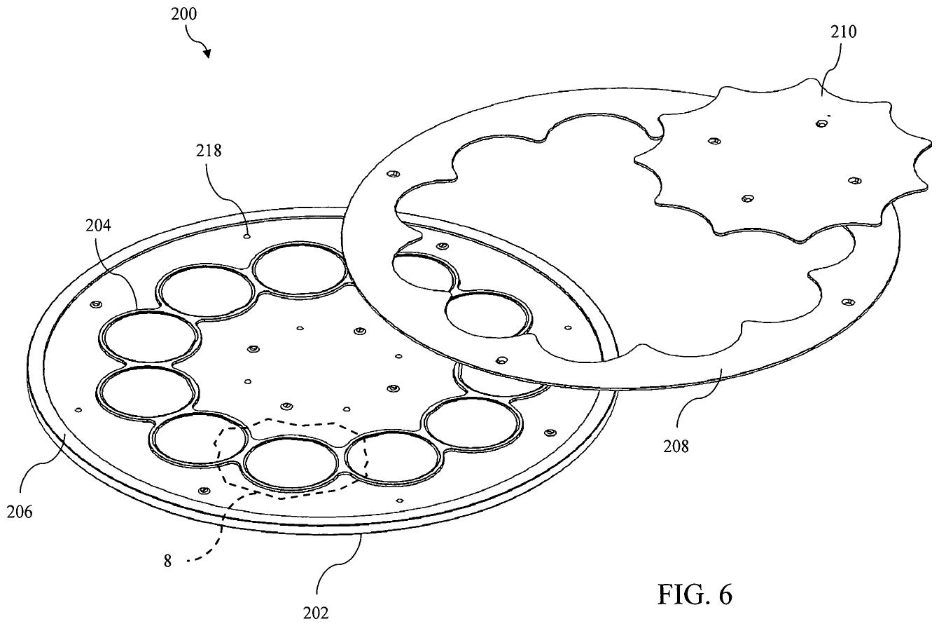

FIG. 5A is a side view of the 11-pocket wafer carrier of FIG. 2. FIG. 5 shows the profiled outer edge of base 202, including rim 206. FIG. 5B is similar to FIG. 5A, except that it depicts a portion of the side view that includes notch 212. Notch 212 can be a curved depression or divot formed in the rim 206. FIG. 6 is an exploded view of the 11-pocket wafer carrier of FIG. 2. FIG. 6 depicts base 202 defining a plurality of built-up pockets 204 and a built-up outer rim 206. In embodiments, the built-up portions 204 and 206 can be created by forming base 202 of a disc-shaped blank and machining away portions other than the edges of the pockets 204 and the outer rim 206. In alternative embodiments, built-up portions 204 and 206 can be added to a flat disc-shaped blank by additively manufacturing the built-up portions 204 and 206, or by attaching one or both pre-fabricated pockets 204 and rim 206 to a flat blank. In embodiments the entire base 202 can be made of the same material. For example, base 202 can be made of a high-temperature alloy (such as an alloy including molybdenum), carbon, or other materials that are capable of being heated to the operating temperature of a CVD system or higher without being damaged or unduly distorted by thermal expansion or contraction.

Outer top cover 208 and inner top cover 210 can be made of the same material as base 202, in embodiments. Alternatively, outer top cover 208 and inner top cover 210 can be made of a different material that has desired thermal transfer characteristics. In one embodiment, outer top cover 208 and inner top cover 210 are made of a quartz material.

In various embodiments, base 202 and the top covers (208, 210) are physically separated by a small gap when assembled. The gap between base 202 and top covers (208, 210) may be maintained by a set of spacers 218 arranged therebetween. In the embodiment shown in FIG. 6, spacers 218 are formed on base 202. Spacers 218 can be formed of the same material as base 202, in embodiments. Where base 202 is made from a machined blank, spacers 218 can be machined into position similar to the machined, raised portions that form pockets 204 and rim 206. In alternative embodiments, spacers 218 can additionally or alternatively be positioned on the surfaces of top covers 208 and 210, rather than (or in addition to) on base 202. Spacers 218 reduce the surface area of direct thermal contact between base 202 and top covers 208 and 210.

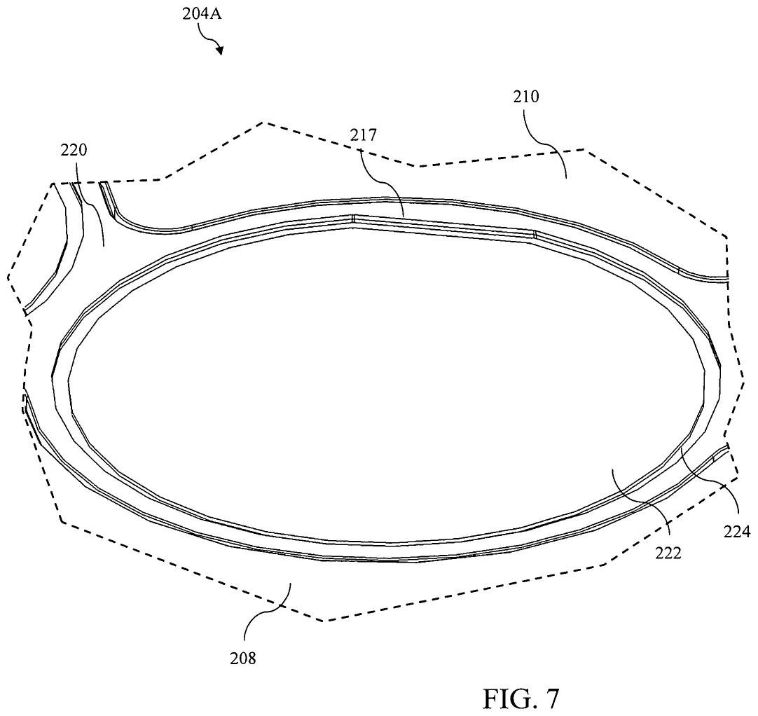

FIG. 7 is a detailed view of one pocket 204A of the 11-pocket wafer carrier of FIG. 2, as indicated by the dashed line on that drawing. Pocket 204A, like the rest of the pockets 204, is adjacent to outer top plate 208 on the radially outer edge (with respect to the reference frame of the wafer carrier) and inner top plate 210 on the radially inner edge (with respect to the reference frame of the wafer carrier). Along the side of pocket 204A that is adjacent to radially inner top plate 210, pocket 204A includes a flat 217. Flats 217 can be used to prevent undesirable rotation of a wafer within pocket 204A during CVD.

Pocket 204A is also adjacent to two other pockets 204, as shown in FIG. 2, and the raised portion of the pocket 204A is coupled to those adjacent pockets 204 at interstitial spaces 220. Interstitial spaces 220 are raised from the remainder of the surface of base 202, often to the same or approximately the same height from the remainder of base 202 as outer top plate 208 and inner top plate 210. Within pocket 204A, and in each of the other pockets 204, a substantially circular platform 222 extends slightly above a trench 224. In various embodiments, platform 222 is not entirely circular, as its overall shape is affected by flat 217. Trench 224 creates a gap of a constant distance between the raised wall of pocket 204A and the platform 222 defined therein.

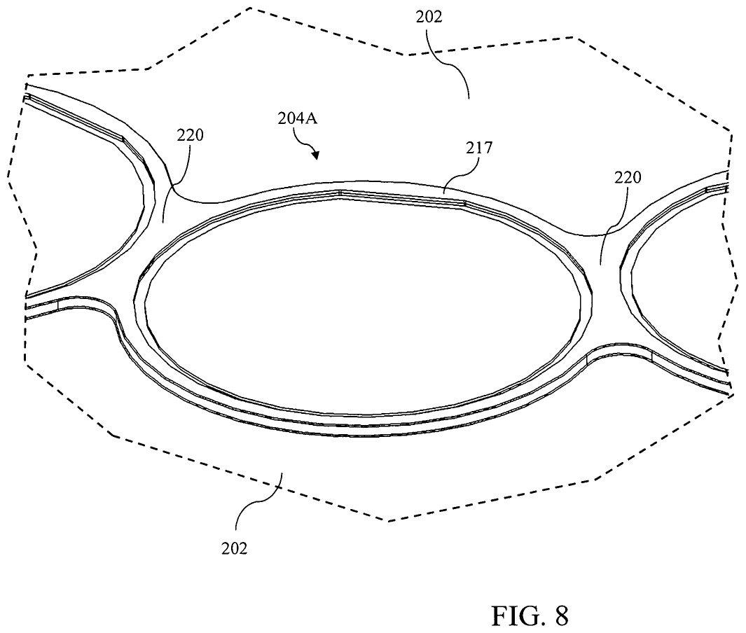

FIG. 8 is a detailed view of one pocket of the 11-pocket wafer carrier of FIG. 2 in the exploded view of FIG. 6. FIG. 8, in contrast with FIG. 7, shows pocket 204A without top plates 208 and 210. Thus, both radially inner and radially outer walls of pockets 204 are each shown as elevated from the remainder of base 202 in this embodiment.

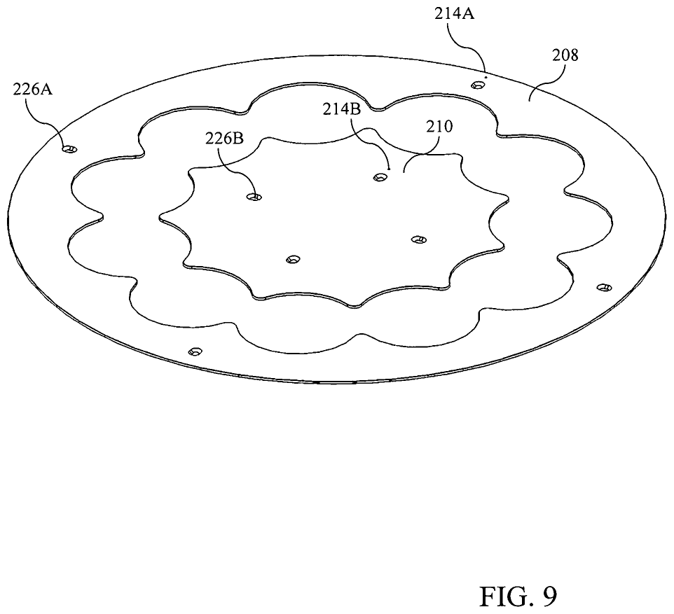

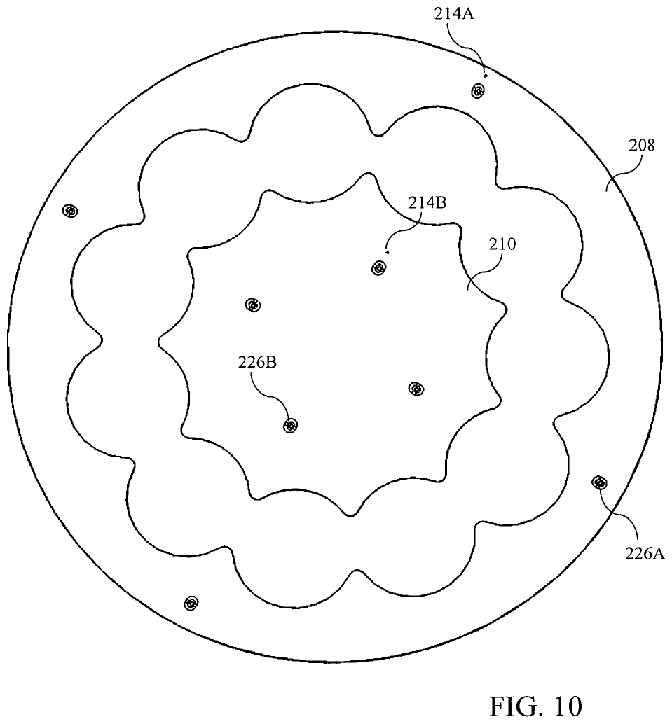

FIGS. 9 and 10 are partial views of wafer carrier 200, in perspective and top views, respectively. FIGS. 9 and 10 show the top covers of the 11-pocket wafer carrier of FIG. 2. As described above, outer top plate 208 and inner top plate 210 each can define an indicator (214A and 214B, respectively). Each of outer top plate 208 and inner top plate 210 can also define a series of countersinks (226A and 226B, respectively) to receive connectors or fasteners as described above. Countersinks 226A and 226B can be sized appropriately to receive a screw head, for example, such that the screw head will remain flush with the remainder of the top surface defined by outer top plate 208 and inner top plate 210.

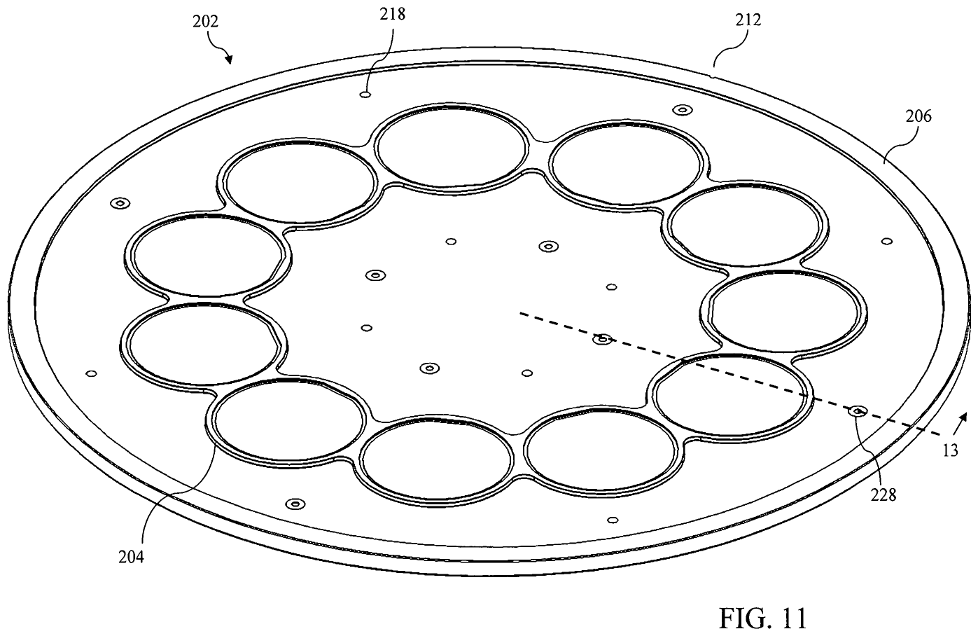

FIG. 11 is a partial perspective view of base 202. Base 202 may include many of the components previously described with respect to FIGS. 2-10, including pockets 204, outer rim 206, notch 212, and spacers 218. FIG. 11 further depicts shafts 228, through which a fastener can pass as described above. In embodiments, shafts 228 can be threaded to engage with a fastener, or alternatively shafts 228 can be smooth to permit a fastener with a rivet, carriage bolt, or similar style pass through. As shown in FIG. 11, each of the shafts 228 includes a countersunk portion, but it should be understood that in various embodiments this may be omitted, depending on the type and size of fastener used to couple top plates (208, 210) to base 202.

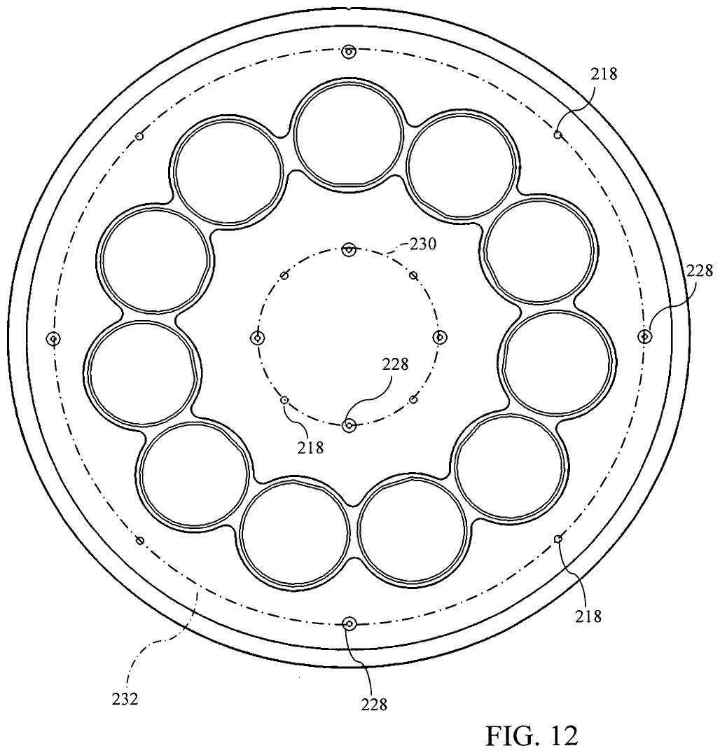

FIG. 12 is a top view of the base of FIG. 11. As shown in FIG. 12, spacers 218 and shafts 228 may be arranged in an alternating pattern about each of two circles. Four spacers 218 and four shafts 228 arranged in radially alternating positions about a radially inner circle 230, and likewise four spacers 218 and four shafts 228 are arranged in radially alternating positions about radially outer circle 232. The spacers 218 arranged along radially inner circle 230 are arranged to hold inner top plate 208, whereas spacers 218 arranged along radially outer circle 232 are arranged to hold outer top plate 210. In alternative embodiments, relatively more or fewer of each of the spacers 218 or shafts 228 can be used. In some embodiments, not all spacers 218 or shafts 228 need be arranged in a circle, and they could be staggered, for example, radially inwards or outwards. In general, the spacers 218 and shafts 228 are positioned to support top plates 208 and 210 in a stable arrangement while minimizing total surface contact area between base 202 and top plates 208 and 210 that would facilitate heat transfer.

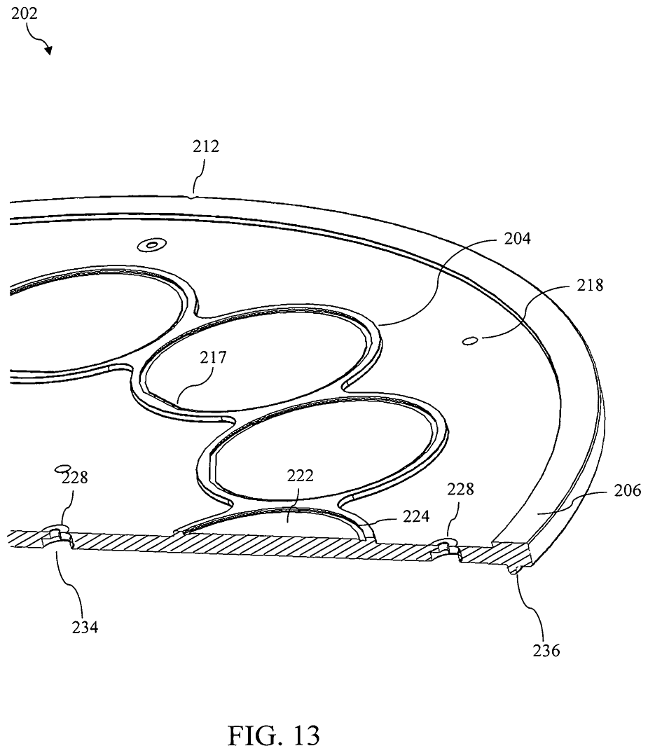

FIG. 13 is a perspective cross-sectional view of the base of FIG. 11, as indicated by the cross-section line 13. FIG. 13 shows countersinks 234 arranged on the bottom surface of base 202. Similar to countersinks 226A and 226B described above, countersinks 234 may not be present in other embodiments, depending on the shape and size of the fasteners used to affix top plates 208 and 210 to base 202. The cross-section shown in FIG. 13 shows the height of pockets 204, including platform 222 and trench 224, from the remainder of base 202. The cross-section shown in FIG. 13 also depicts collar 236, which supports base 202 on an adjacent structure (not shown).

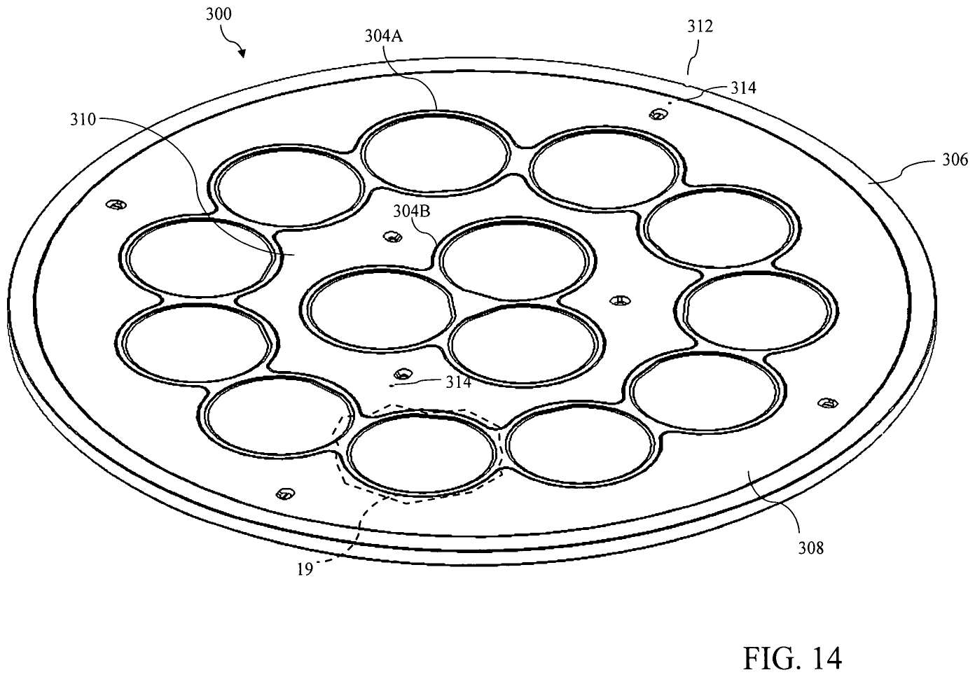

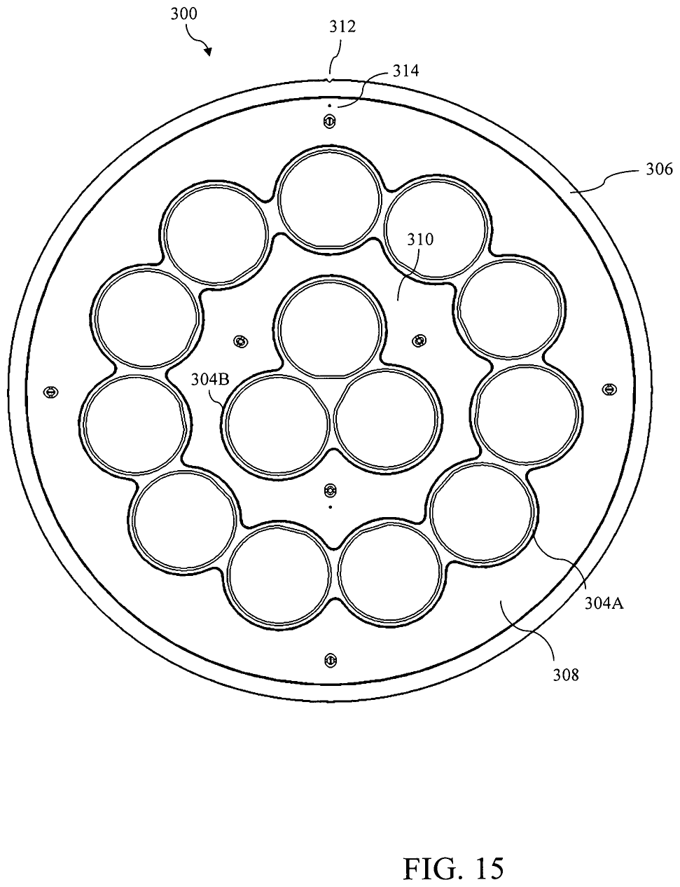

FIG. 14 is a perspective view of a 14-pocket wafer carrier 300 according to an embodiment. Wafer carrier 300 is similar to wafer carrier 200 described above with respect to FIGS. 2-13, and similar components are assigned reference numerals herein that are iterated by 100. Thus, for example, notch 312 is similar to notch 212 in that it can be used to align indicators 314 during installation of radially outer top cover 308 and radially inner top cover 310, similar to how indicators 214 are aligned with notch 212 during installation of radially inner top cover 208 and radially outer top cover 210. Wafer carrier 300 may include an outer rim 306, similar to outer rim 206 of FIGS. 2-13.

In addition to the various components described with respect to the embodiments of FIGS. 2-13, wafer carrier 300 includes additional pockets. Specifically, wafer carrier 200 has a base 202 that was built up to define a single ring of wafer pockets 204. In contrast, wafer carrier 300 of FIG. 14 has two built-up sections that define a first set of pockets 304A and a second set of pockets 304B. Additionally, wafer carrier 300 is different from wafer carrier 200 in that the shapes of top covers 308 and 310 are different to accommodate the radially central set of pockets 304B. FIG. 15 is a top view of the 14-pocket wafer carrier of FIG. 14.

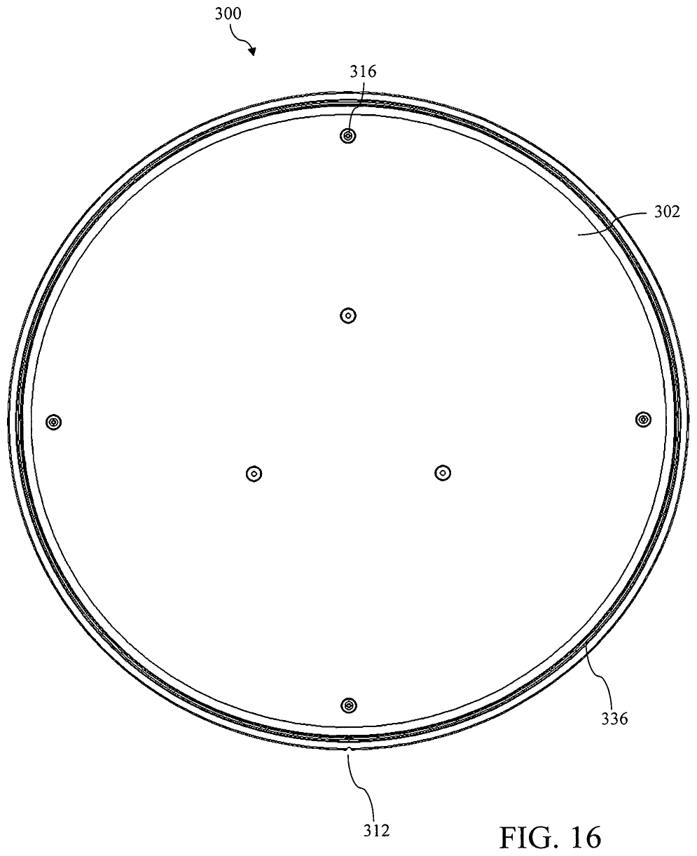

FIG. 16 is a bottom view of the 14-pocket wafer carrier 300 of FIGS. 14 and 15. The bottom view of wafer carrier 300 shows one side of base 302, similar to base 202 of FIGS. 2-13. Base 302 defines collar 336, which can support base 302 on an adjacent device (not shown). The bottom view in FIG. 16 also depicts seven connectors 316, which can be used to couple the top plates 308 and 310 to the base 302. As in the other embodiment described above, a variety of fasteners and connectors are usable in alternative embodiments, and in greater or smaller numbers, as needed to affix top plates 308 and 310 to the base 302.

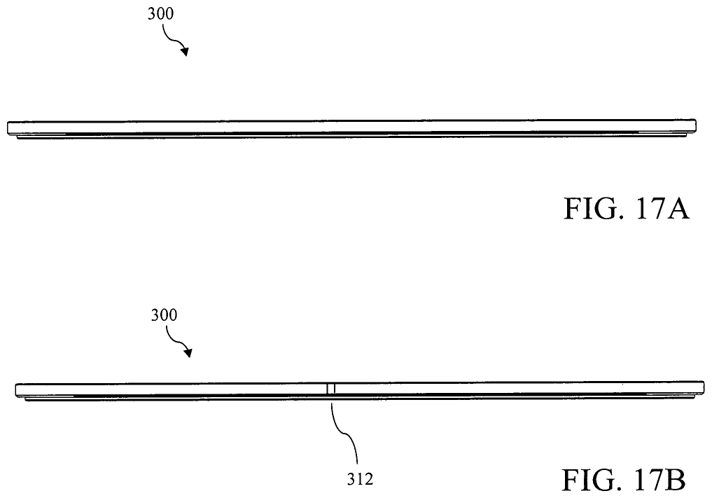

FIG. 17A is a side view of wafer carrier 300. As described above with respect to the embodiment of wafer carrier 200, FIG. 17B shows the same side view but at a portion that includes notch 312.

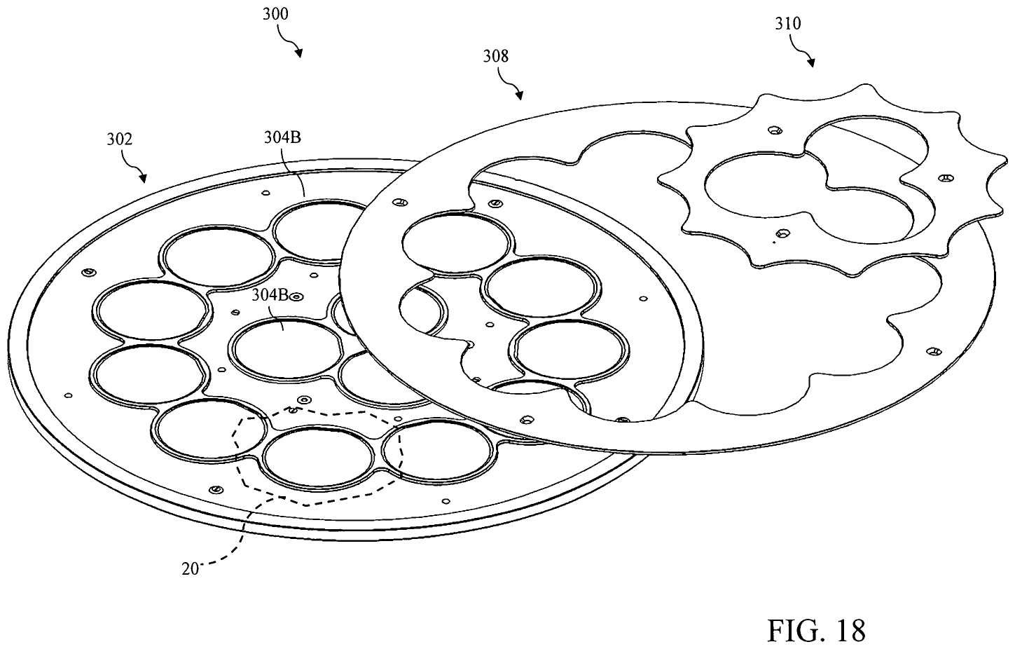

FIG. 18 is an exploded view of the wafer carrier 300 of FIG. 14. As shown in FIG. 18, base 302 defines outer ring of pockets 304A and inner ring of pockets 304B, and top plates 308 and 310 are shaped to fit therebetween.

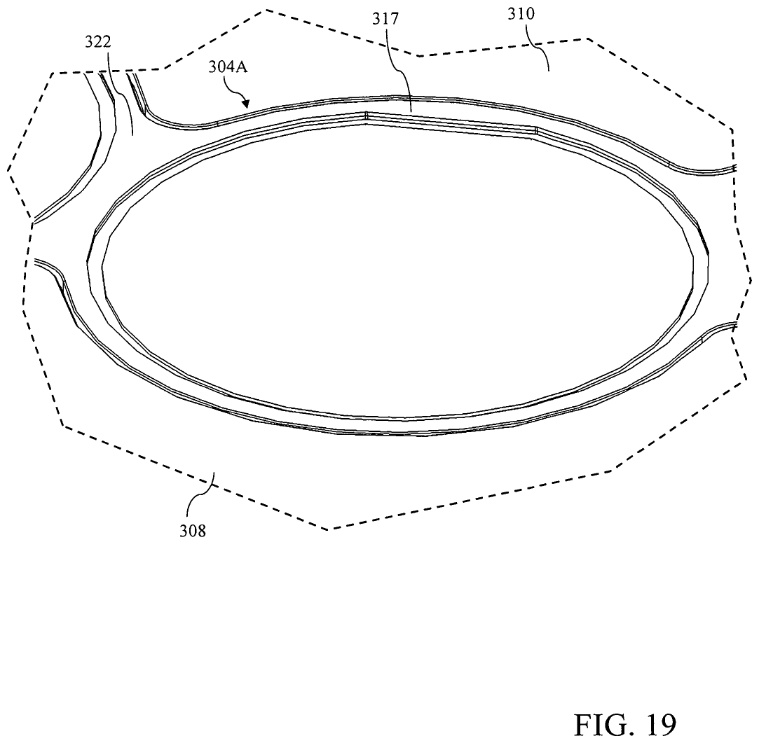

FIG. 19 is a detailed view of one pocket of the 14-pocket wafer carrier of FIG. 14, as indicated by detail section 19 from that drawing. Interstitial spaces 322 separate the individual pockets and are raised to approximately the same height as the top surface of top covers 308 and 310. Flats 317 are provided to prevent undesirable rotation of wafers within each of the pockets 304A, similar to flats 217 described above with respect to FIGS. 2-13. Similar flats can be found in the wafers that make up the radially inner set 304B.

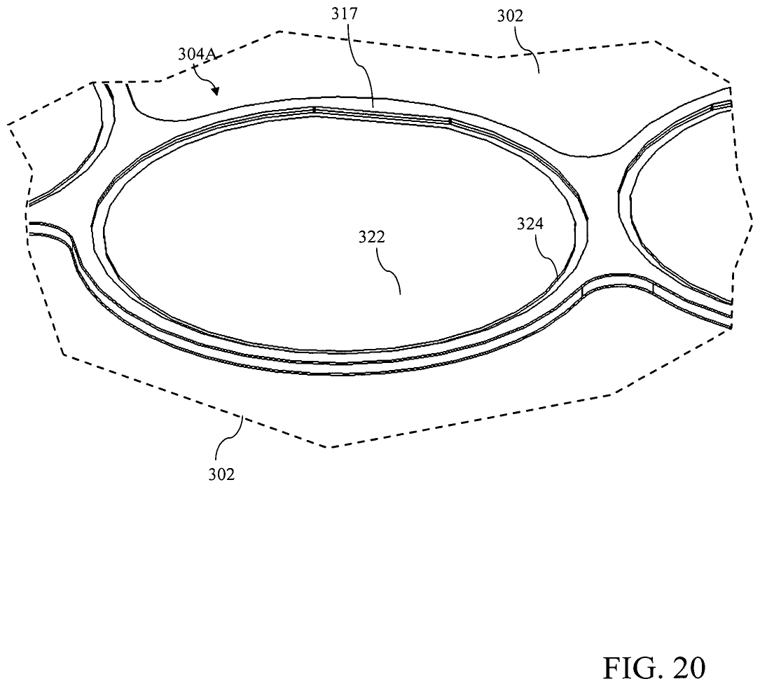

FIG. 20 is a detailed view of one pocket of the 14-pocket wafer carrier of FIG. 14 in the exploded view of FIG. 18, as indicated by detail section 20 in that drawing. In contrast to FIG. 19, top covers 308 and 310 are removed such that only base 302 is shown.

In both FIGS. 19 and 20, platform 322 and trench 324 are visible. A platform 322 may be configured to support a wafer within each pocket 304A and is surrounded by a trench 324 that separates platform 322 from the peripheral wall of the wafer pocket 304A, including flat 318.

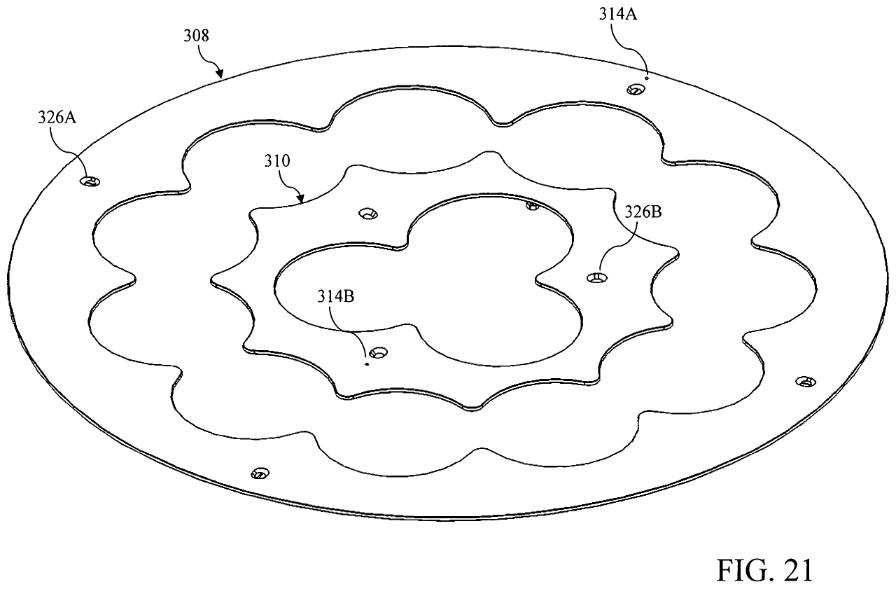

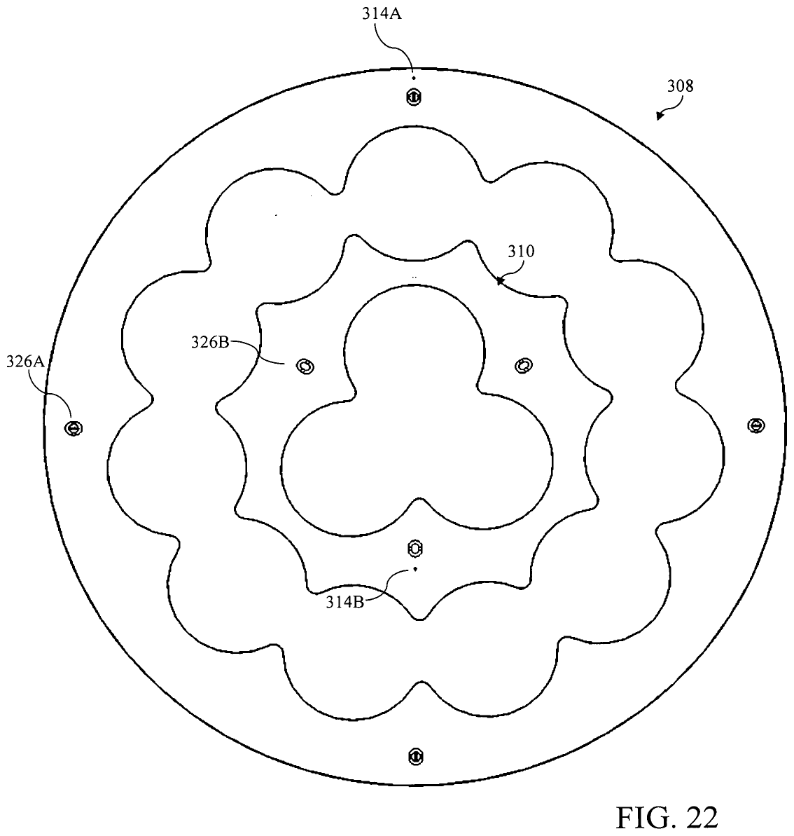

FIG. 21 is a perspective partial view of the 14-pocket wafer carrier 300 of FIG. 14, showing the top covers thereof (308 and 310). FIG. 22 is a top view of the top covers 308 and 310. Radially outer top cover 308 may include countersinks 326A that are each configured to receive a fastener to couple top cover 308 to base 302. Radially inner top cover 310 likewise may include countersinks 326B that are each configured to receive a fastener to couple top cover 310 to base 302. Radially outer top cover 308 and radially inner top cover 310 each may include an indicator (314A and 314B, respectively) for aligning the covers as they are being installed.

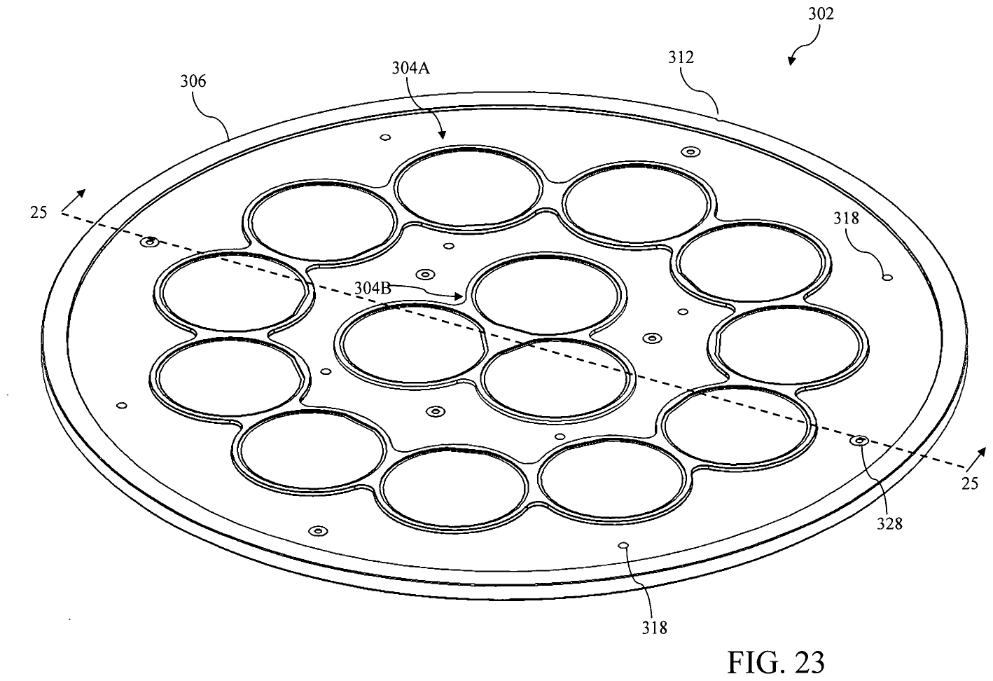

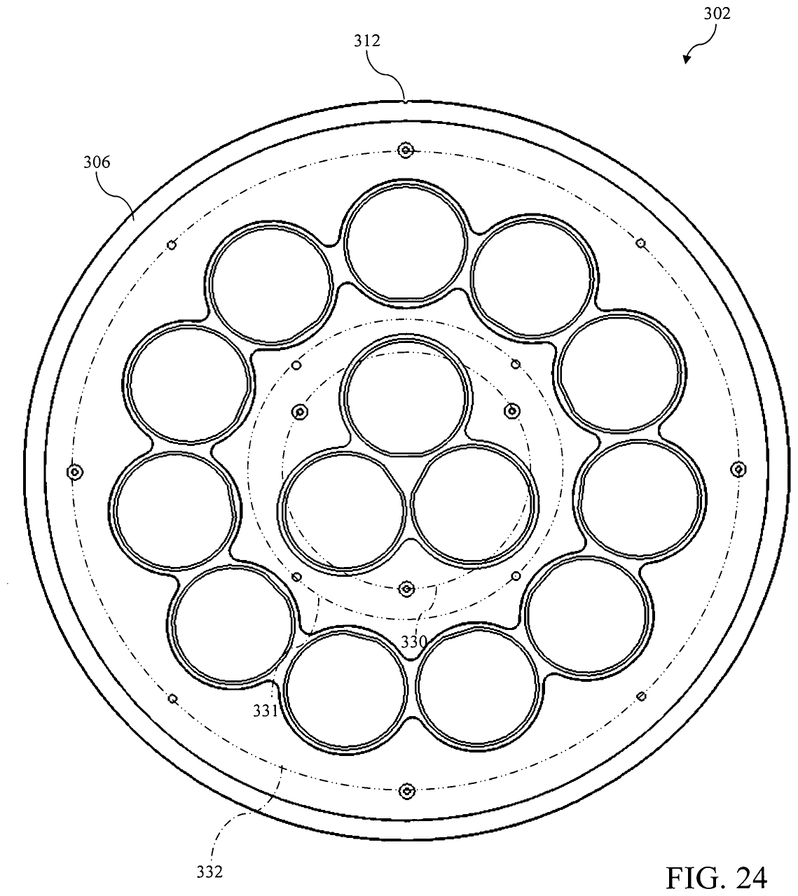

FIG. 23 is a partial perspective view of the 14-pocket wafer carrier 300 of FIG. 14, showing the base 302 thereof, and FIG. 24 is a top view of the same. As shown in FIGS. 23 and 24, shafts 328 and spacers 318 are arranged along circles concentric with the overall shape of the wafer carrier. Unlike the embodiment shown in FIGS. 2-13, however, the spacers 318 and shafts 328 are not necessarily arranged along the same circles. Rather, radially inner shafts 328 are arranged along first circle 330 that is radially innermost, while spacers 318 are arranged along a second circle 331 that is radially outward from first circle 330. Both spacers 318 and shafts 328 are arranged along a third circle 332 that is radially outermost.

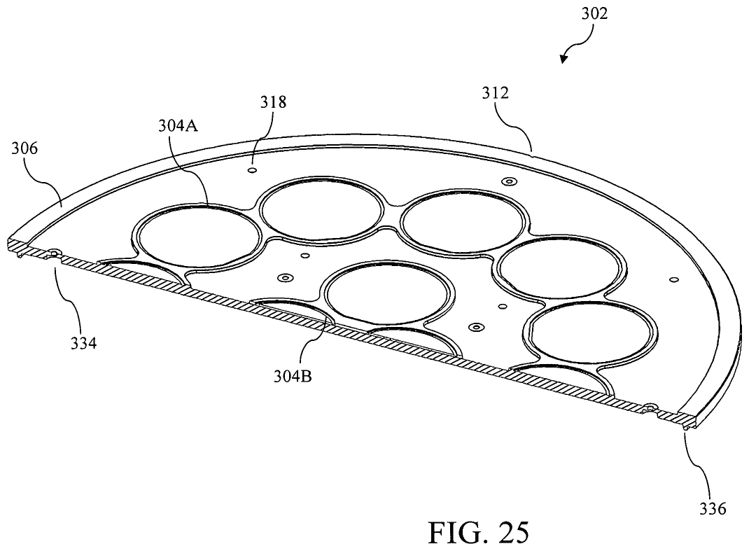

FIG. 25 is a cross-sectional view of the base of FIG. 23. FIG. 25 shows that the pockets 304A of the radially outer ring are integrally formed with the base 302, whereas the pockets 304B of the radially inner ring (not shaded in the cross-sectional view) are a separate piece of material formed on top of base 302. Additionally, like base 202 of FIGS. 2-13, base 302 includes countersinks 334 configured to retain a portion of a fastener. FIG. 25 also shows ridge 336 is a part of base 302, integrally formed with the same material.

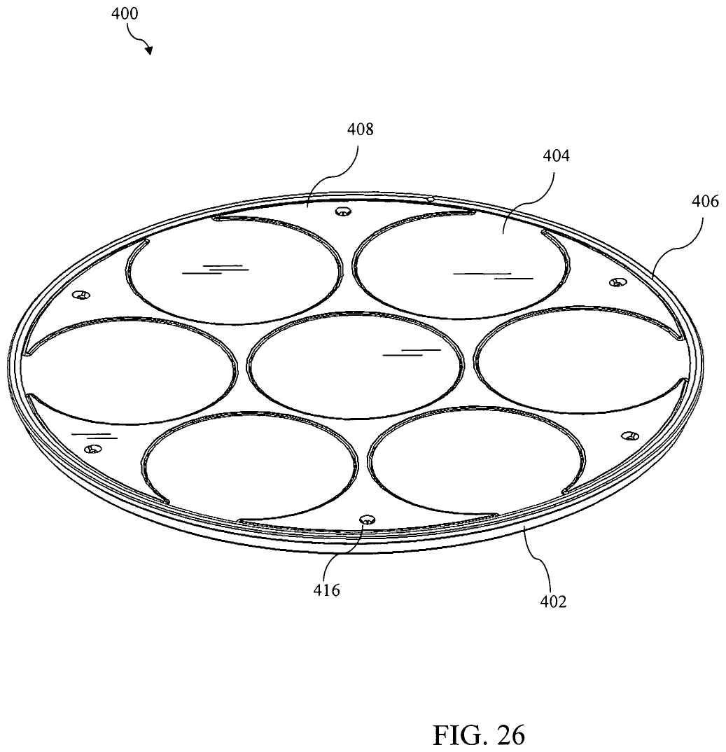

FIG. 26 is a perspective view of a wafer carrier 400 according to another embodiment. Wafer carrier 400 includes a base 402 including a series of pockets 404 that are accessible through apertures in a top plate 408. In use, wafers are held above (but not on) pockets 404 by a top plate 408 and prevented from radially outward movement at least partially by rim 406. Top plate 408 is held to base 402 by a plurality of fasteners 416, which (as described above) can be screws, bolts, rivets, or any other mechanical fastener.

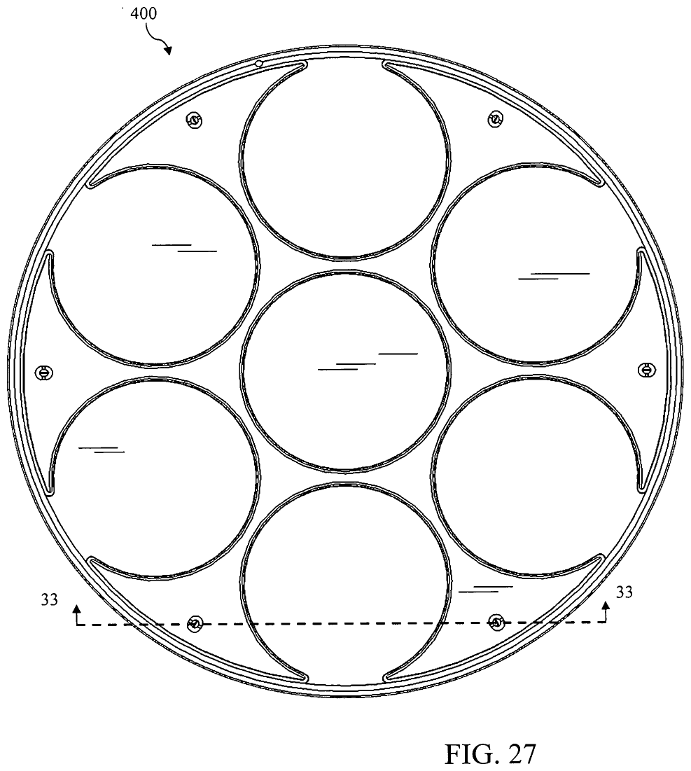

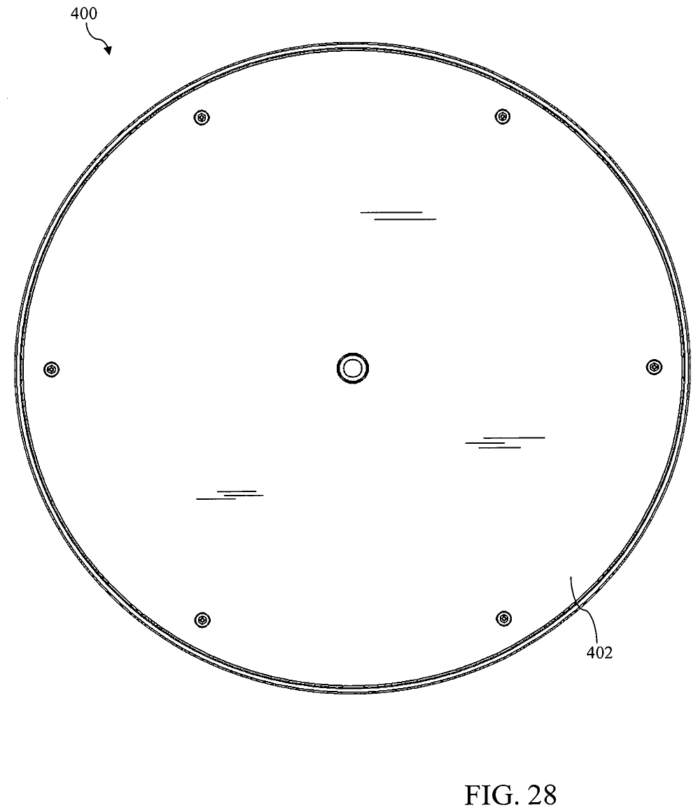

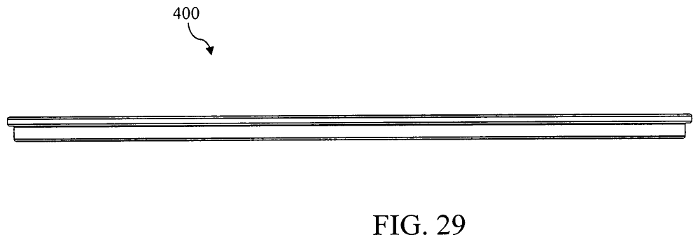

FIG. 27 is a top view of the wafer carrier 400 of FIG. 26, FIG. 28 is a bottom view, and FIG. 29 is a side view of the same. As described above, various other drive mechanisms could be used rather than a single spindle design that corresponds to the bottom view of FIG. 28.

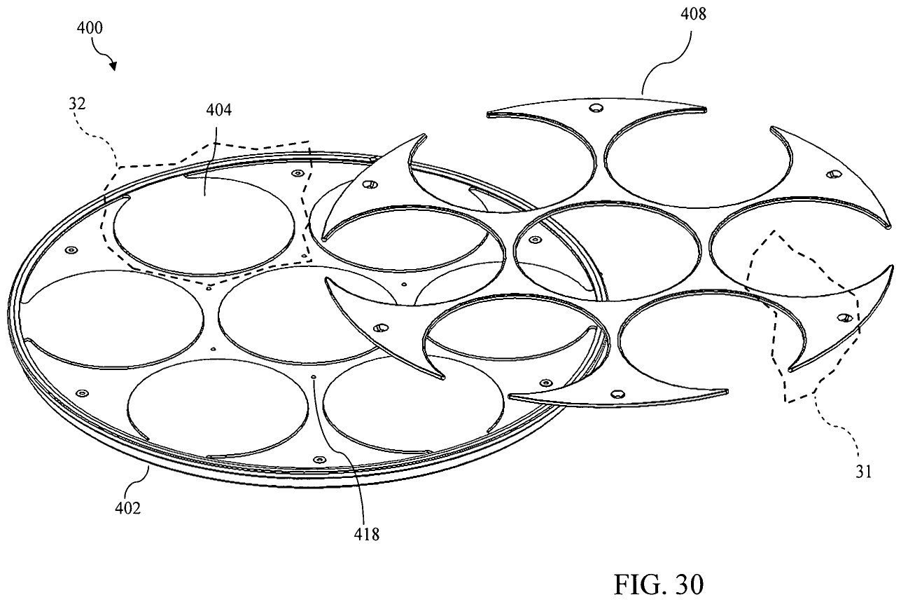

FIG. 30 is an exploded view of the wafer carrier 400 of FIG. 26. As shown in the exploded view, each of the pockets 404 is raised off of the base 402. The amount that each pocket 404 is raised can be, for example, between about 0.25 mm and about 2 mm. The exploded view of FIG. 30 also shows spacers 418, which hold top plate 408 at a distance from base 402. Spacers 418 separate top plate 408 from base 402 and reduce thermal transfer therebetween. Spacers 418 can be the same or a different thickness compared to pockets 404. In the embodiment shown in FIG. 30, spacers 418 are less thick than the height of pockets 404.

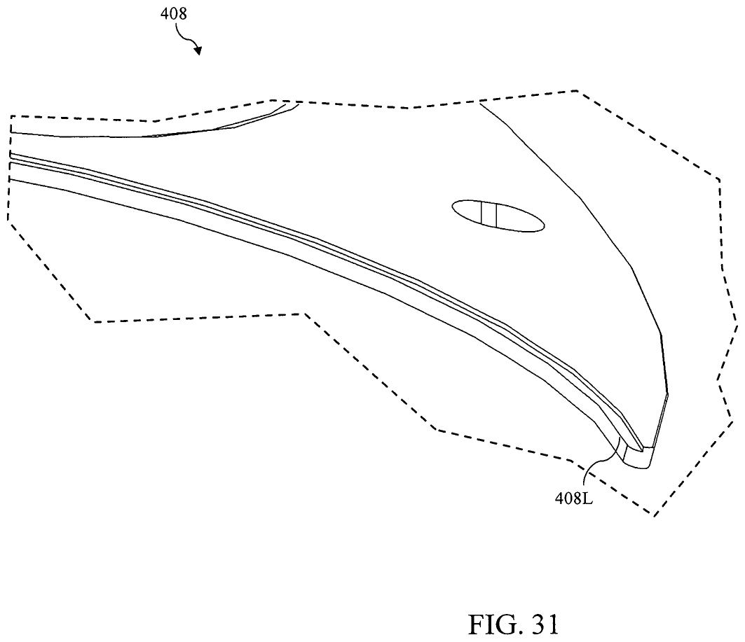

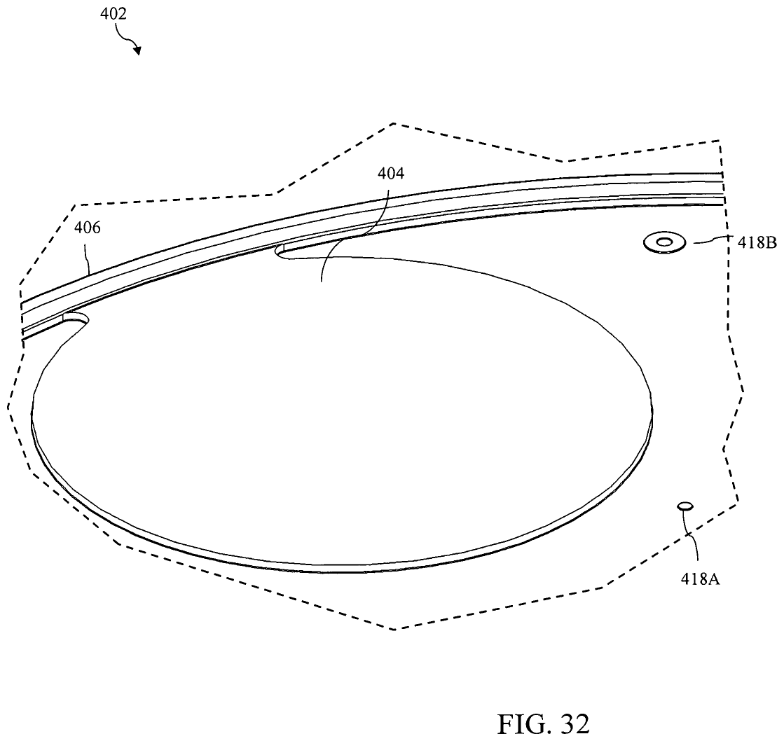

FIGS. 31 and 32 are detailed views as called out in FIG. 30. Detailed view 31 of FIG. 30, shown in FIG. 31, is a portion of top plate 408. In particular, FIG. 31 shows ledge 408L, which is a portion of top plate 408 on which a wafer can be positioned during CVD processing. Detailed view 32 of FIG. 30, shown in FIG. 32, is a portion of base 402, specifically one of the pockets 404 therein. FIG. 32 also shows a thermal cover spacer 418A that separates the top cover 408 from the base 402, as well as a through-hole 418B through which fasteners 416 can be arranged to hold top cover 408 to base 402.

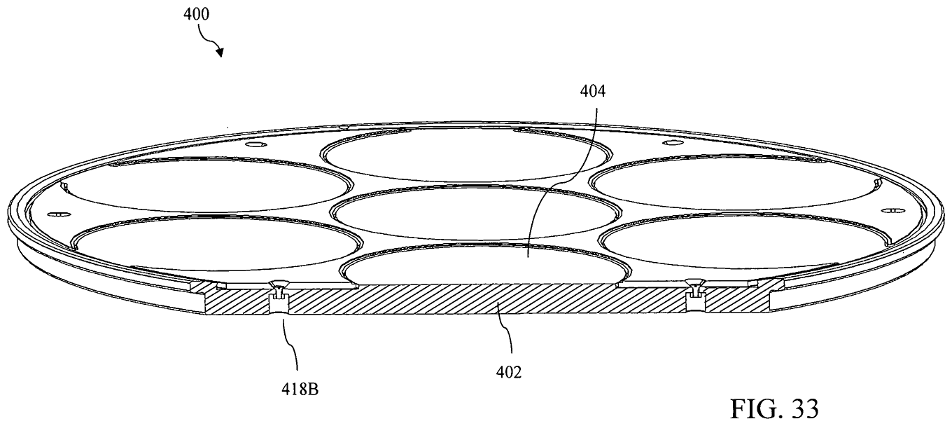

FIG. 33 is a cross-sectional view of the wafer carrier 400 of FIGS. 26-33, along the cross-section 33-33 shown in FIG. 27. Base 402 is shown with increased thickness at pockets 404, and defining apertures 418B through which fasteners can pass as described with respect to FIG. 32.

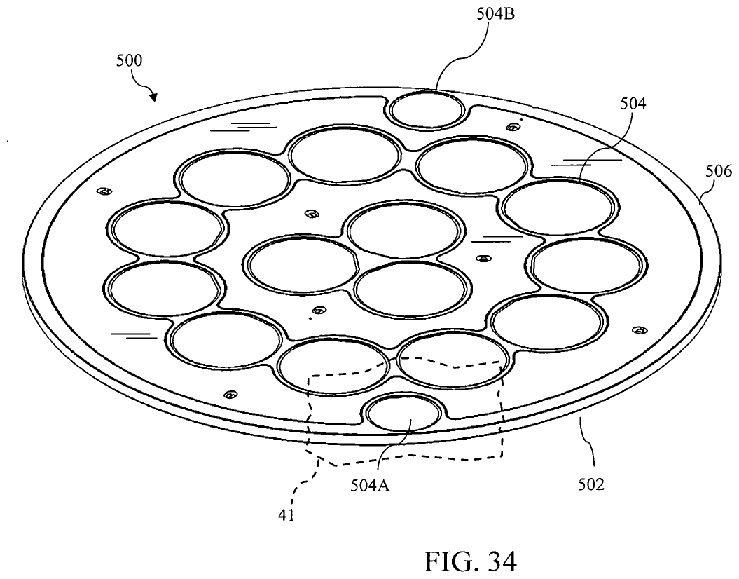

FIG. 34 is a perspective view of a fourth embodiment of a wafer carrier. The wafer carrier 500 shown in FIG. 34 has sixteen pockets 504 arranged on a base 502, two of which (outer pockets 504A and 504B) are arranged adjacent rim 506. By positioning outer pockets 504A and 504B adjacent the rim 506, measurements such as deflectometry, reflectometry, pyrometry, or emissivity -compensated pyrometry can be conducted via a radially-outer window above the wafer carrier (not shown in this drawing, but for example a window passing through the far left or right side of the injector block 104 shown in FIG. 1). Various adjustments to the process conditions can be controlled based on the measured characteristics at the outer pockets 504A and 504B. For example, the reactor temperature can be modified, or the relative proportions of the precursor gases can be changed, or the location where the gas is input into the reactor chamber can be changed, the rotation speed of a susceptor can be changed, or in some circumstances (such as when the desired wafer thickness has been reached) the CVD process can be stopped altogether. The specific actions that might be taken depend on the particular structure being grown and the desires of the CVD operator. Often the available window space for taking such measurements, or for other uses, is relatively limited and thus the ability to take useful measurements at a less-desirable portion of the reactor, such as the radially-outer region, central window space is retained for other uses.

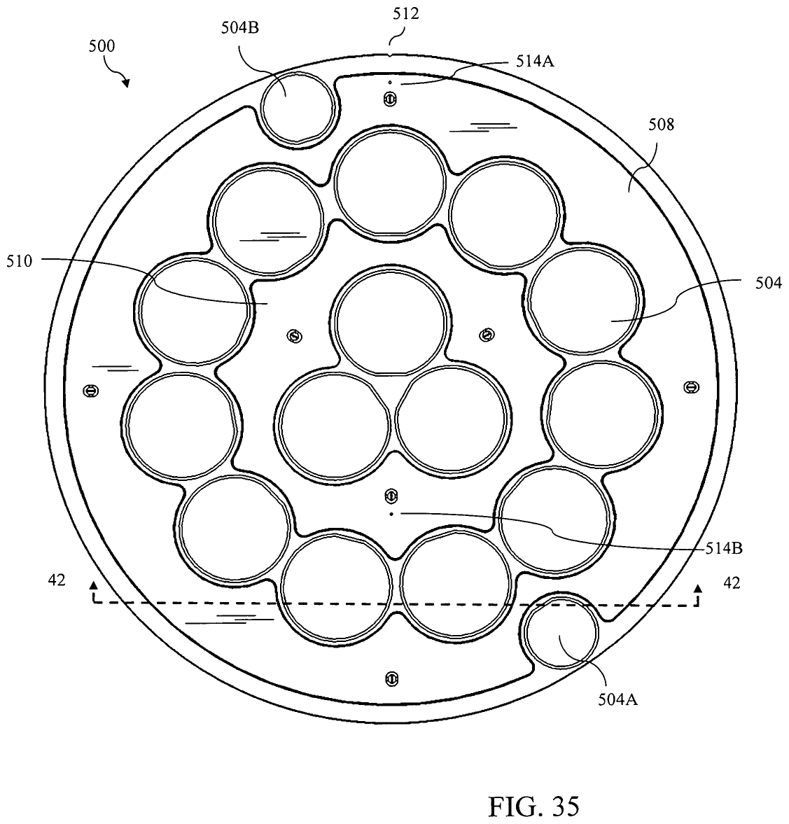

FIG. 35 is a top view of the reactor 500. As shown in FIG. 35, a radially-outer top cover 508 and a radially-inner top cover 510 are arranged between the various groups of pockets 504. In order to align the top covers 508 and 510 with the body 502, radially-outer top cover 508 has a first fiducial 514A and radially-inner top cover 510 has a second fiducial 514B that are aligned with a notch 512.

FIGS. 36A and 36B show side views of the wafer carrier 500. Around most of its circumference, the side views of wafer carrier 500 are substantially uniform, showing only the outer edge of body 502. On the front, however, the smooth edge is interrupted by notch 512.

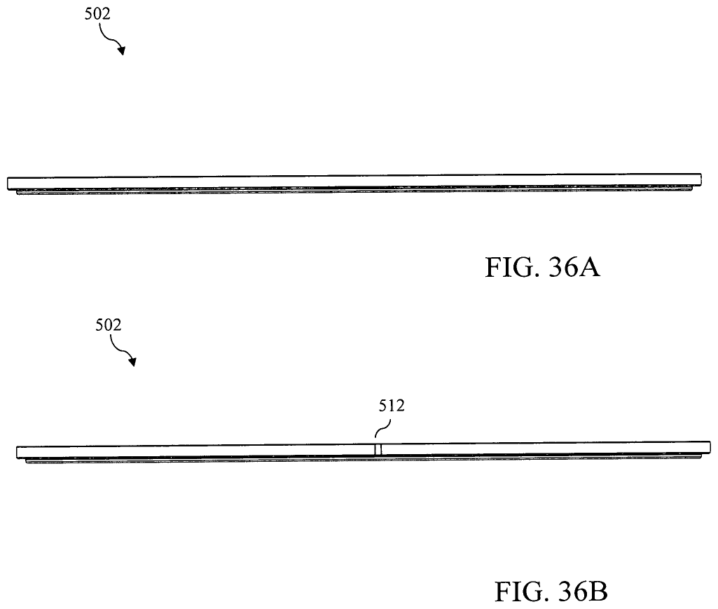

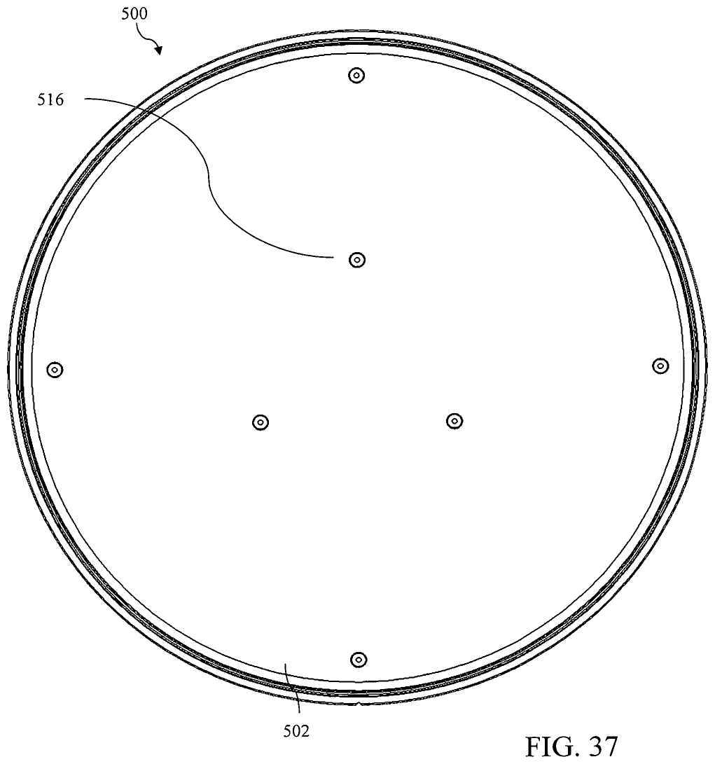

FIG. 37 is a bottom view of wafer carrier 500. As described above with respect to the other embodiments, various drive mechanisms can be employed, as well as varying arrangements of fasteners, in various embodiments.

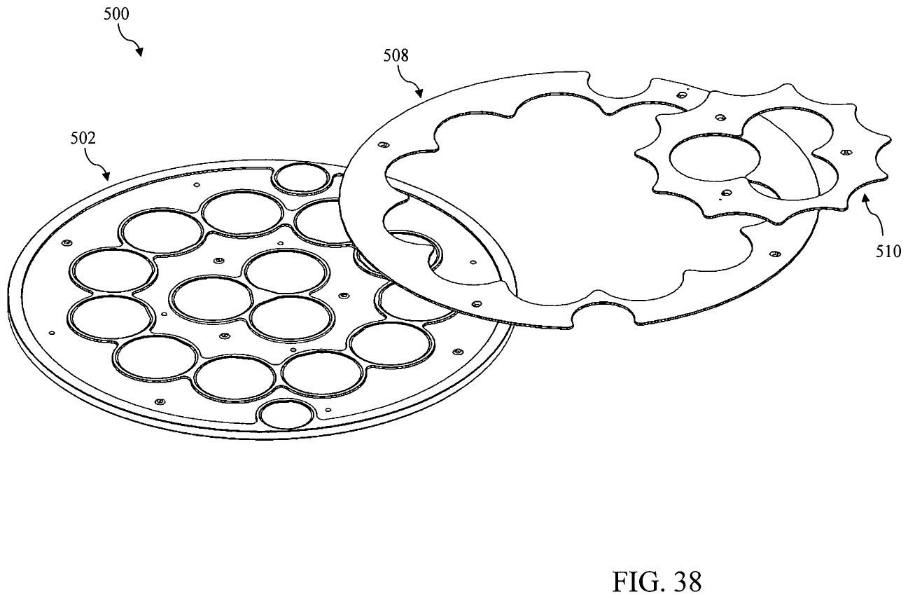

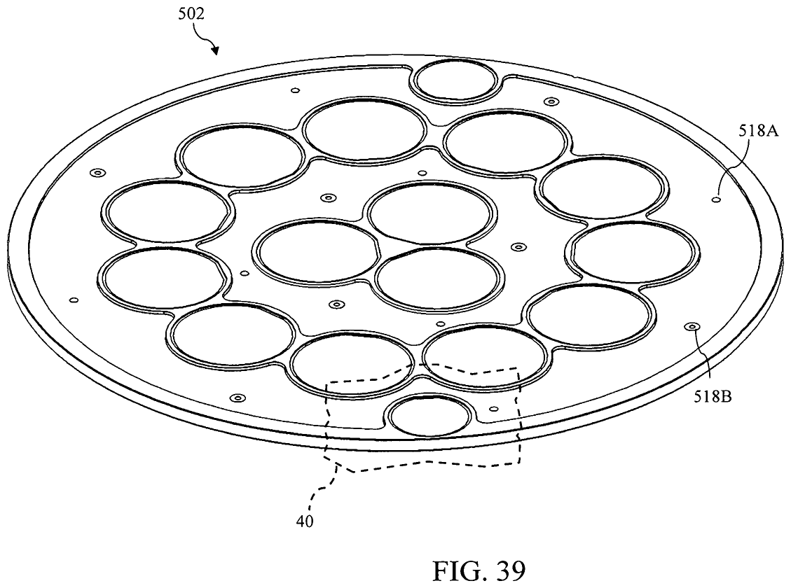

FIG. 38 is an exploded view of wafer carrier 500, and FIG. 39 is a detailed view of just one portion of that exploded view. Specifically, FIG. 39 shows base 502, with top plates 508 and 510 removed. With top plates 508 and 510 removed, spacers 518A and through-holes 518B are exposed. Spacers 518A hold top plates 508 and 510 at a distance from base 502 during operation, while through-holes 518B are apertures through which fasteners 516 can pass to hold top plates 508 and 510 to base 502. Additionally, in some embodiments through-holes 518B include raised portions to support top plates 508 and 510 adjacent the fasteners 516.

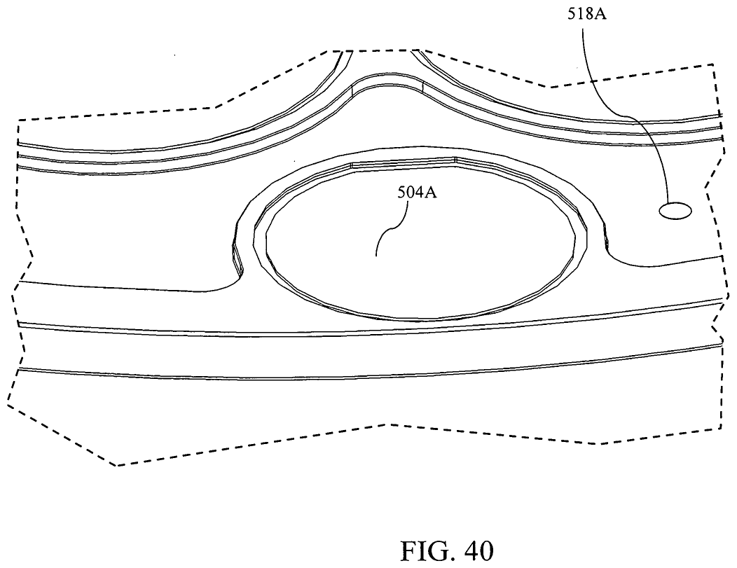

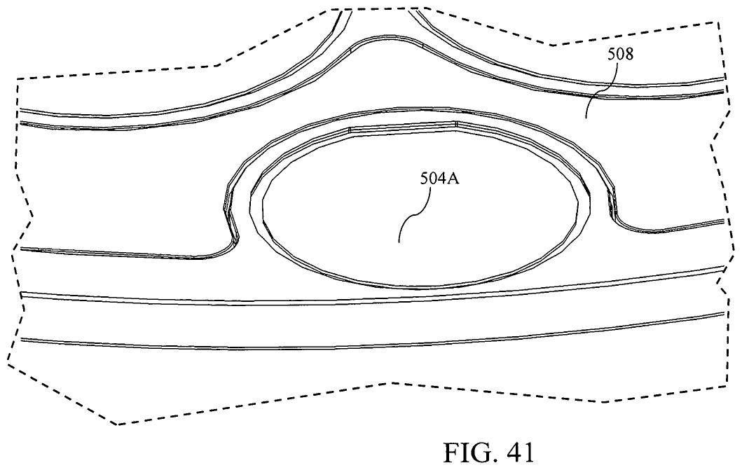

FIG. 40 is a detailed view of the portion 40 identified in FIG. 39. FIG. 41 shows the same portion, but with top plate 508 in place, based on the detailed view 41 shown in FIG. 34.

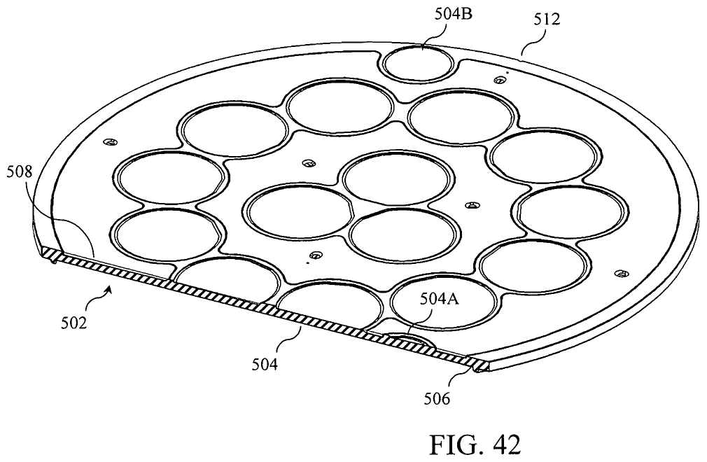

FIG. 42 is a cross-sectional view 42-42 shown in FIG. 35. In the cross-sectional view, as described above with respect to the other embodiments, the various thicknesses of the base 502, cover plate 508, and the base 502 at the pockets 504 and rim 506 are shown.

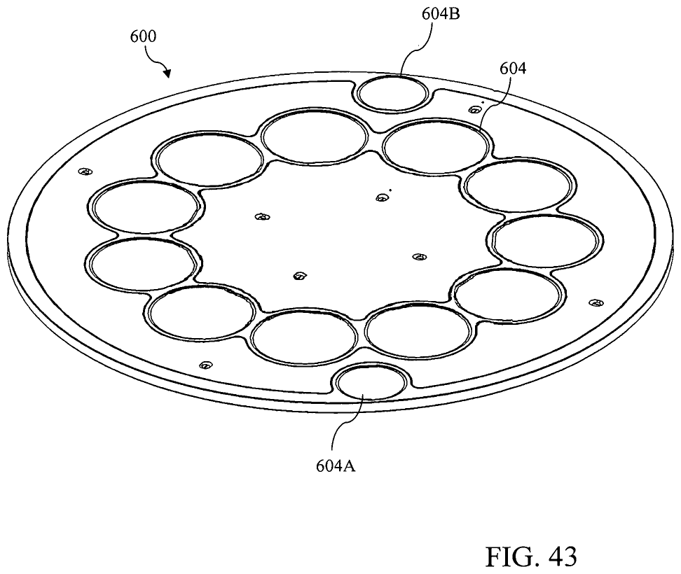

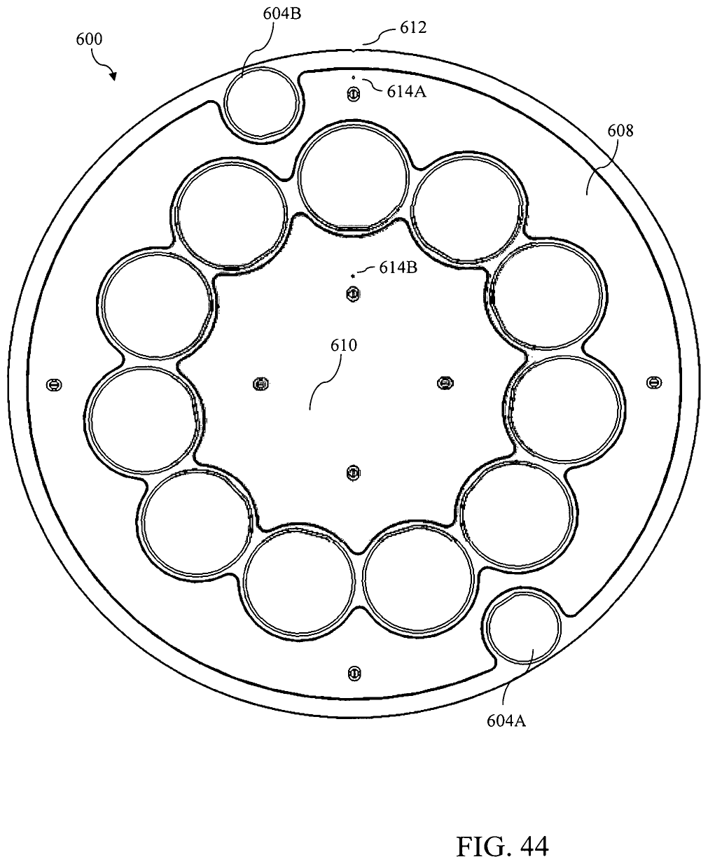

FIG. 43 is a perspective view of another embodiment of a wafer carrier 600 having the 11-pocket design of central pockets 604 previously described with respect to FIGS. 2-13, and also the outer pockets 604A and 604B previously described with respect to FIGS. 34-42. FIG.

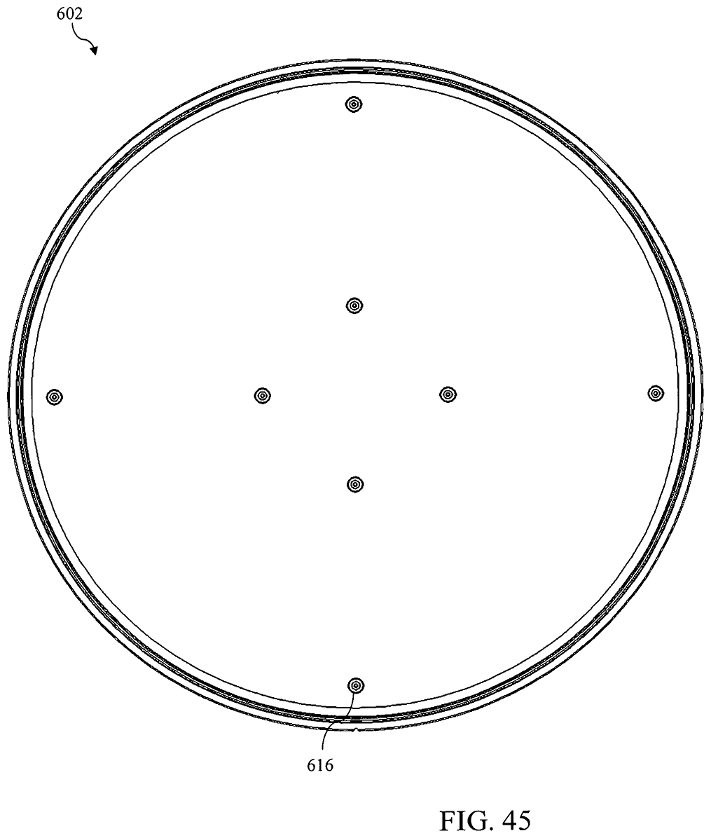

44 is a top view of the wafer carrier 600 of FIG. 43, and more clearly shows notch 612 and fiducials 614A and 614B for aligning the radially outer top cover 608 and the radially outer top cover 610, respectively, as they are attached to base 602. FIG. 45 is a bottom view of the base 602 (and therefore also the wafer carrier 600 generally), though it should be understood that based on the different arrangements of fasteners 616, the bottom view could vary.

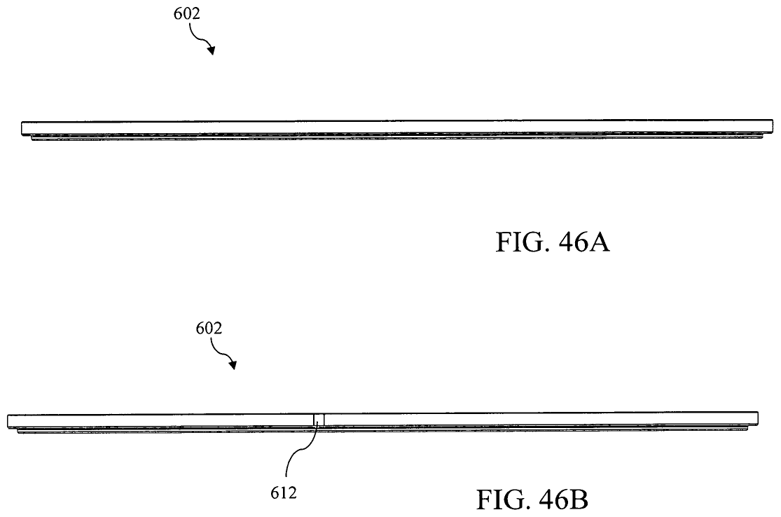

FIGS. 46A and 46B show side views of wafer carrier 600. Similar to previously-described embodiments, the outer side view is substantially smooth and uniform but for notch 612 shown in FIG. 46B.

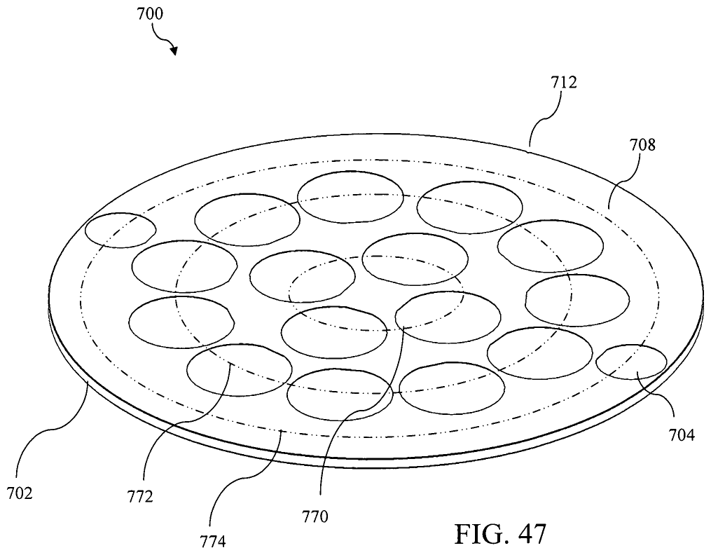

FIGS. 47-50 depict another embodiment. As shown in FIG. 47, a wafer carrier assembly 700 includes three rings of pocket 704. Pockets 704 are arranged about an inner ring 770, a middle ring 772, and an outer ring 774. About each of these rings, the pockets are evenly spaced. That is, the geometric center of the pockets about each ring (similar to the fasteners arranged about rings described above) is coincident with a central axis of the wafer carrier body generally. Thermal cover 708 is arranged to cover the portions of the wafer carrier body 702 that do not correspond to pockets 704, and as shown in FIGS. 47-50 the thermal cover 708 is not split into inner and outer rings as in other embodiments described above. Rather, each of the pockets 704 is isolated from the other pockets 704 and is an island defined within the thermal cover 708. As with the embodiments described above, a notch 712 can be used to align the thermal cover 708 and the wafer carrier body 702 for use in a CVD process.

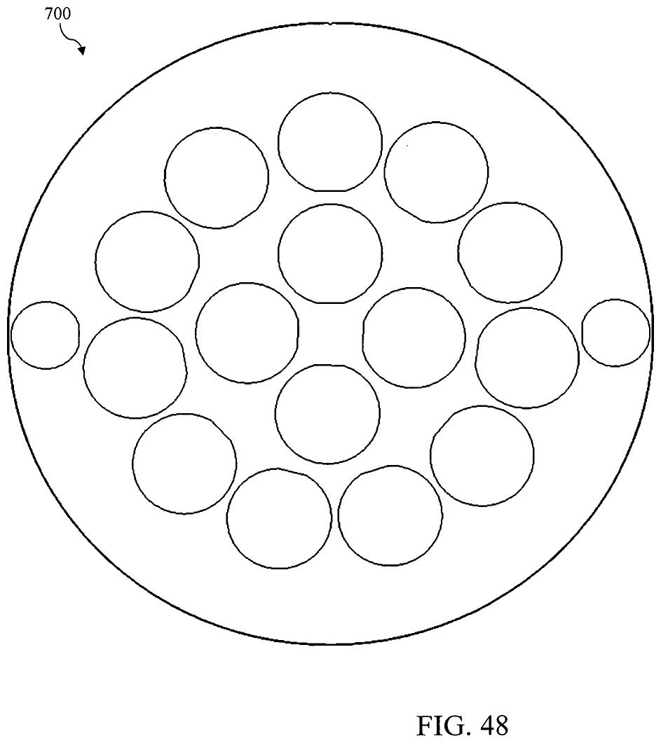

FIG. 48 is a top plan view of the wafer carrier assembly shown in FIG. 47. The pockets in wafer carrier assembly 700 are shown without depth, and it should be understood that in various embodiments the pockets could have a depth based on the thickness of the thermal cover 708 and the height of the pockets 704, similar to the other embodiments described above. In various embodiments this depth will be different depending on the desired thickness of substrate and, in some cases, final wafer carrier thickness.

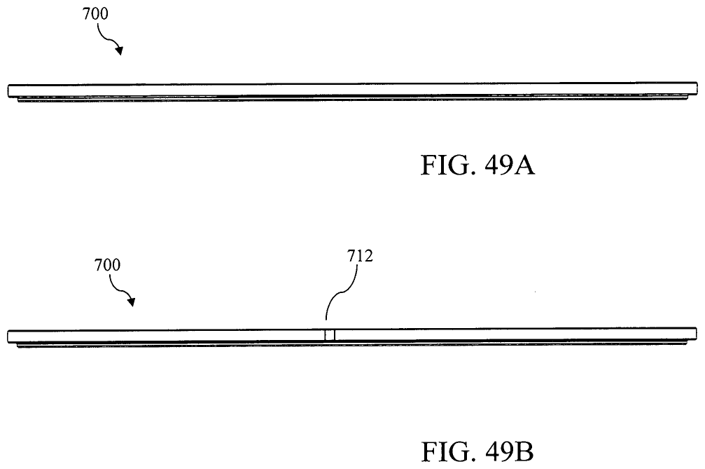

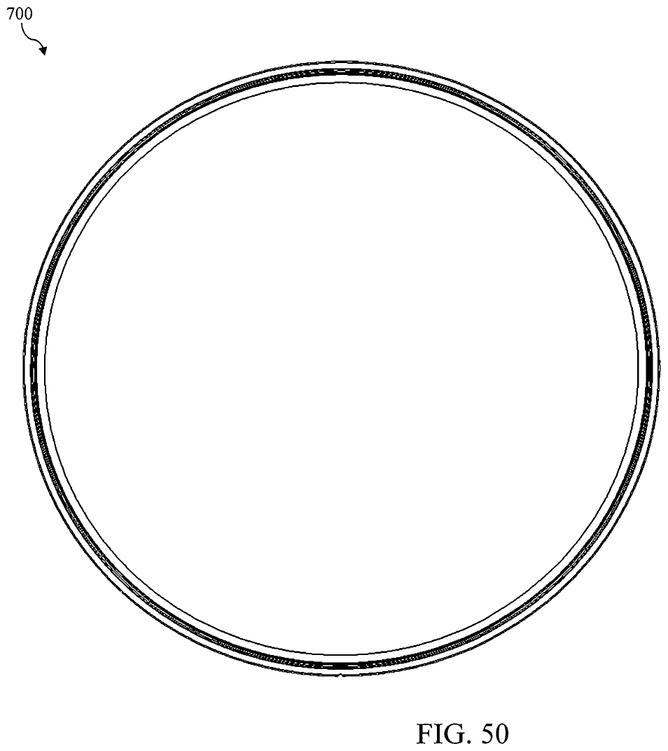

FIGS. 49A and 49B show wafer carrier assembly 700 from the side. FIG. 49A shows the left, right, and back views of the wafer carrier assembly, which are all identical to one another in the embodiment shown in FIGS. 47-50. FIG. 49B shows a front view of the wafer carrier assembly 700, which differs from the left, right, and back views in that it includes notch 712. FIG. 50 shows a bottom view of the wafer carrier assembly 700.

It should be understood that the individual steps used in the methods of the present teachings may be performed in any order and/or simultaneously, as long as the teaching remains operable. Furthermore, it should be understood that the apparatus and methods of the present teachings can include any number, or all, of the described embodiments, as long as the teaching remains operable.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions. Moreover, reference in the specification to “one embodiment,” “an embodiment,” or “some embodiments” means that a particular feature, structure, or characteristic, described in connection with the embodiment, is included in at least one embodiment of the teaching. The appearances of the phrase “in one embodiment” in various places in the specification are not necessarily all referring to the same embodiment.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. § 112(f) are not to be invoked unless the specific terms “means for” or “step for” are recited in a claim.

1. A wafer carrier assembly for use in a system for growing epitaxial layers on one or more wafers by chemical vapor deposition (CVD), the wafer carrier assembly comprising:
a wafer carrier body formed symmetrically about a central axis, and including a generally planar bottom surface that is situated perpendicularly to the central axis and a top surface that is generally parallel to the top surface;
at plurality of pockets arranged on the wafer carrier body, wherein each of the plurality of pockets extends from the top surface and is generally circular but for a flat wafer rotation prevention portion, and wherein each of the plurality of pockets includes a trench circumscribed by a ridge at an outer periphery thereof;
a plurality of spacers arranged on the top surface; and
a thermal cover portion configured to engage with the wafer carrier body at the spacers, wherein the thermal cover has a thickness corresponding to a height of the plurality of pockets, a height of the lip, and a height of the spacers.

2. The wafer carrier assembly of claim 1, wherein the thermal cover is coupled to the wafer carrier body by a plurality of fasteners.

3. The wafer carrier assembly of claim 2, wherein each of the fasteners passes through a spacer.

4. The wafer carrier assembly of claim 2, wherein the fasteners are threaded.

5. The wafer carrier assembly of claim 1, wherein the plurality of pockets are arranged in a ring that is concentric with the central axis.

6. The wafer carrier assembly of claim 1, wherein the wafer carrier body defines a notch and the thermal cover defines an indicator that are configured to be aligned when the thermal cover is fastened to the wafer carrier body.

7. The wafer carrier assembly of claim 1, wherein the thermal cover is a radially outer thermal cover, and wherein the wafer carrier assembly further comprises a radially inner thermal cover.

8. The wafer carrier assembly of claim 7, wherein the radially inner thermal cover and the radially outer thermal cover each define an indicator configured to be aligned with a notch defined in the wafer carrier body.

9. The wafer carrier assembly of claim 7, further comprising a second plurality of spacers arranged on the top surface, wherein the radially inner thermal cover is configured to engage with the top surface at the second plurality of spacers.

10. The wafer carrier assembly of claim 5, wherein the ridges corresponding to each of the plurality of wafers overlap at interstitial spaces such that the plurality of pockets forms a continuous ring.

11. The wafer carrier assembly of claim 10, wherein the thermal cover is a radially outer thermal cover, and wherein the wafer carrier assembly further comprises a radially inner thermal cover, and wherein the radially outer thermal cover is arranged radially outwards from the continuous ring while the radially inner thermal cover is arranged radially inwards from the continuous ring.

12. The wafer carrier assembly of claim 11, wherein each of the radially inner thermal cover and the radially outer thermal cover are arranged concentrically about the central axis.

13. The wafer carrier assembly of claim 2, wherein the fasteners are each arranged in one or more circles that are concentric about the central axis, and wherein the fasteners arranged in each of the circles are evenly spaced about that circle.

14. The wafer carrier assembly of claim 11, further comprising at least one outer pocket directly adjacent a radially outer rim that circumscribes the top surface.

15. A wafer carrier assembly comprising:
a wafer carrier body formed symmetrically about a central axis, and including a generally planar bottom surface that is situated perpendicularly to the central axis and a top surface that is generally parallel to the top surface, wherein the top surface is circumscribed by an outer rim that is substantially circular with a center at the central axis;
at plurality of pockets arranged on the wafer carrier body, wherein each of the plurality of pockets extends from the top surface and in a generally circular shape, and wherein each of the plurality of pockets extends beyond the generally circular shape to the outer rim;
a plurality of spacers arranged on the top surface; and
a thermal cover portion configured to engage with the wafer carrier body at the spacers, wherein the thermal cover has a thickness corresponding to a height of the plurality of pockets, a height of the lip, and a height of the spacers, and wherein the thermal cover defines a ledge configured to hold a wafer substrate during chemical vapor deposition.

16. The wafer carrier assembly of claim 15, wherein the thermal cover is coupled to the wafer carrier body by a plurality of fasteners.

17. The wafer carrier assembly of claim 16, wherein each of the fasteners passes through a spacer.

18. The wafer carrier assembly of claim 15, wherein the wafer carrier body defines a notch and the thermal cover defines an indicator that are configured to be aligned when the thermal cover is fastened to the wafer carrier body.

19. The wafer carrier assembly of claim 15, further comprising at least one outer pocket directly adjacent the outer rim.
